(19) United States
(12) Patent Application Publication
(10) Pub. No.: US 2008/0102406 A1
(43) Pub. Date: May 1, 2008

(54) LIGHT SENSITIVE PLANOGRAPHIC PRINTING PLATE MATERIAL AND MANUFACTURING PROCESS OF PRINTING PLATE EMPLOYING THE SAME

(76) Inventor: Junichi FUKAWA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/925,430

(22) Filed: Oct. 26, 2007

(30) Foreign Application Priority Data
Oct. 31, 2006 (JP) JP2006-295648

(51) Int. Cl. G03C 1/73; G03F 7/20

(52) U.S. Cl. 430/286.1; 430/302

(57) ABSTRACT

Disclosed is a light sensitive planographic printing plate material comprising a support and provided thereon, a light sensitive layer containing a spectral sensitizer, a polymerization initiator, a polymerizable monomer and a polymeric binder, wherein the light sensitive planographic printing plate material comprises a surfactant represented by the following formula (SF1) or (SF2),

R₁—O—(R₂—O)ₙ—H Formula (SF1)

R₃O—[CH₂CH(CH₃)O]ₗ(CH₂CH₂O)ₘ—H Formula (SF2)

This application is based on Japanese Patent Application No. 2006-295648, filed on Oct. 31, 2006 in Japanese Patent Office, the entire content of which is hereby incorporated by reference.

### FIELD OF THE INVENTION

The present invention relates to a light sensitive planographic printing plate material used in a computer to plate (hereinafter also referred to as CTP) system and a manufacturing process of a printing plate employing the same.

### BACKGROUND OF THE INVENTION

In recent years, a digital technique in which image information is electronically processed, stored, and output is widely used. In a plate-making process of a printing plate for off-set printing, so-called a CTP system, which records digital image data directly on a light sensitive printing plate material employing highly directed laser light, has been developed and practically used.

In a printing field in which relatively high printing durability is required, a negative working light sensitive planographic printing plate material is known which comprises a polymerizable light sensitive layer containing a polymerizable compound (see for example, Japanese Patent O.P.I. Publication Nos. 1-105238 and 2-127404).

Argon laser (488 nm) and YD-YAG laser (532 nm) are known as a light source for exposure of a light sensitive planographic printing plate material comprising a polymerizable light sensitive layer. However, these light sources have problems in that processability is low under a safelight, and productivity of a printing plate is insufficient, since they are not sufficiently high in output power.

Recently, a compact laser with high output power emitting continuously a short wavelength (350 to 450 nm) light is easily obtained.

In order to improve the productivity or safelight property above, a printing plate material adapted to this short wavelength laser light has been developed. A printing plate material with improved safelight property under yellow light is known, which comprises a light sensitive layer containing a biimidazole compound disclosed in for example, Japanese Patent O.P.I. Publication No. 2001-194782. Further, a polymerizable light sensitive composition with high sensitivity and now sublimation property is known, which comprises a hexaarylbiimidazole having a substituted aryl group, e.g., an alkyl-substituted aryl group, disclosed in Japanese Patent O.P.I. Publication No. 2004-137152.

However, the printing plate material and the light sensitive composition have problems in that sensitivity is still insufficient and development properties are insufficient.

Generally, a photopolymerizable light sensitive planographic printing plate material is imagewise exposed, optionally pre-heated, washed with water to remove an oxygen shielding layer, subjected to development to remove a light sensitive layer at unexposed portions (non-image portions), washed with water, and then subjected to finisher-gumming treatment for hydrophilization, whereby a planographic printing plate is manufactured. In the development in which a light sensitive layer at unexposed portions is removed in the manufacturing process above of a printing plate, an aqueous alkaline developer with a pH of not less than 12.5 is generally used.

Recently, use of an alkaline developer with a low pH has been required in view of processability, safety and environmental problems. However, a developer with a low pH is basically low in dissolution of a light sensitive layer, and has problems in that development is insufficient and contamination is likely to be produced at non-image portions.

### SUMMARY OF THE INVENTION

The present invention has been made in view of the above. An object of the invention is to provide a light sensitive planographic printing plate material with high sensitivity and high storage stability, which not produces contamination at non-image portions even when developed with a low pH developer, and a manufacturing process of a printing plate employing the same.

### DETAILED DESCRIPTION OF THE INVENTION

The above object of the present invention can be attained by the following constitution.

1. A light sensitive planographic printing plate material comprising a support and provided thereon, a light sensitive layer containing a spectral sensitizer, a polymerization initiator, a polymerizable monomer and a polymeric binder, wherein the light sensitive planographic printing plate material comprises a surfactant represented by the following formula (SF1) or (SF2),

R₁—O—(R₂—O)ₙ—H Formula (SF1)

wherein R₁ represents a substituted or unsubstituted branched alkyl group having a total carbon atom number of not more than 20 or a substituted or unsubstituted branched alkyl amino group having a total carbon atom number of not more than 20; R₂ represents a substituted or unsubstituted alkylene group having a carbon atom number of from 1 to 10; n represents an integer of 2 to 100, provided that plural R₂s may be the same or different,

R₃O—[CH₂CH(CH₃)O]ₗ(CH₂CH₂O)ₘ—H Formula (SF2)

wherein R₃ represents an alkyl group having a carbon atom number of from 4 to 10; l represents an integer of from 1 to 3; and m represents an integer of from 1 to 100.

2. The light sensitive planographic printing plate material of item 1 above, wherein the light sensitive layer contains the surfactant represented by formula (SF1) or (SF2).

3. The light sensitive planographic printing plate material of item 1 above, wherein an oxygen shielding layer containing polyvinyl alcohol is provided on the light sensitive layer.

4. The light sensitive planographic printing plate material of item 3 above, wherein the oxygen shielding layer contains the surfactant represented by formula (SF1) or (SF2).

5. The light sensitive planographic printing plate material of item 1 above, wherein the polymerization initiator is an iron-arene complex.

6. The light sensitive planographic printing plate material of item 1 above, wherein the polymerization initiator is a hexaarylbiimidazole.

7. The light sensitive planographic printing plate material of item 1 above, wherein the spectral sensitizer is a coumarin derivative represented by formula (CS),

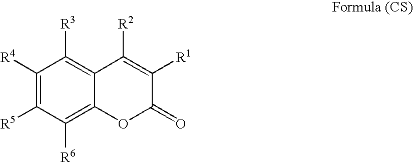

wherein R¹ through R⁶ independently represent a hydrogen atom or a substituent.

8. The light sensitive planographic printing plate material of item 1 above, wherein the polymerizable monomer is a polymerizable compound having in the molecule a hydroxyl group.

9. The light sensitive planographic printing plate material of item 1 above, wherein the light sensitive layer contains, as the polymeric binder, a homopolymer or copolymer of N-vinyl pyrrolidone.

10. A manufacturing process of a planographic printing plate comprising the steps of (a) imagewise exposing the light sensitive planographic printing plate material of item 1 above, employing a laser, and (b) removing the light sensitive layer at unexposed portions at 25° C. with an aqueous solution with a pH of 3.0 to 9.0 containing a water soluble resin and a surfactant.

11. The manufacturing process of item 10 above, wherein the laser has an emission wavelength of from 350 to 450 nm.

12. The process of item 10 above, wherein the surfactant contained in the aqueous solution is a surfactant represented by formula (SF1) or (SF2).

13. The manufacturing process of item 10 above, between the steps (a) and (b), further comprising the step of heating the exposed light sensitive planographic printing plate material so that the surface temperature of the exposed material is from 80 to 160° C.

14. A manufacturing process of a planographic printing plate comprising the steps of (a) imagewise exposing the light sensitive planographic printing plate material of claim 3, employing a laser, (b) removing the oxygen shielding layer and a part of the light sensitive layer of the exposed material, employing water, and (c) then removing the light sensitive layer at unexposed portions with an aqueous solution with a pH at 25° C. of 3.0 to 9.0 containing a water soluble resin and a surfactant.

15. The manufacturing process of item 14 above, wherein the laser has an emission wavelength of from 350 to 450 nm.

16. The process of item 14 above, wherein the surfactant contained in the aqueous solution is a surfactant represented by formula (SF1) or (SF2).

17. The manufacturing process of item 14 above, between the steps (a) and (b), further comprising the step of heating the exposed light sensitive planographic printing plate material so that the surface temperature of the exposed material is from 80 to 160° C.

The light sensitive planographic printing plate material of the invention comprises a support and provided thereon, a light sensitive layer containing a spectral sensitizer, a polymerization initiator, a polymerizable monomer and a polymeric binder, an oxygen shielding layer containing polyvinyl alcohol being optionally provided on the light sensitive layer, wherein the light sensitive planographic printing plate material comprises a surfactant represented by formula (SF1) or (SF2) above.

The present invention will be explained below.

### (Surfactant)

The light sensitive planographic printing plate material of the invention comprises a surfactant (hereinafter also referred to as the surfactant in the invention) represented by formula (SF1) or (SF2) above. The surfactant in the invention may be contained in a component layer constituting the light sensitive planographic printing plate material. It is preferred that the surfactant in the invention is contained in the light sensitive layer. It is suitable that the surfactant in the invention is contained in the oxygen shielding layer optionally provided on the light sensitive layer.

Incorporation of the surfactant in the invention in the component layer minimizes or prevents contaminations occurring at non-image portions during development, as compared with a method in which development is carried out employing a developer containing a surfactant in a considerable amount. This effect is markedly exhibited when development is carried out with a solution with a low pH which is low in dissolution of light sensitive layer. As described later, the effect is markedly exhibited when a light sensitive layer at unexposed portions is removed at 25° C., employing an aqueous solution with a pH of from 3.0 to 9.0 containing a water soluble resin and a surfactant.

The content of the surfactant in the component layer of the light sensitive planographic printing plate material is not specifically limited, but it is preferably from 0.01 to 10% by weight and more preferably from 0.1 to 5% by weight, based on the total solid content of the component layer.

It is preferred that the aqueous solution described above contains a surfactant represented by formula (SF1) or (SF2). The content of the surfactant in the aqueous solution is not specifically limited, but it is preferably from 0.01 to 20% by weight and more preferably from 0.1 to 10% by weight.

Next, the surfactant represented by formula (SF1) or (SF2) will be explained in detail.

### (Compound Represented by Formula (SF1))

In formula (SF1), R₁ represents a substituted or unsubstituted branched alkyl group having a total carbon atom number of not more than 20 or a substituted or unsubstituted branched alkyl amino group having a total carbon atom number of not more than 20, and R₂ represents a substituted or unsubstituted alkylene group having a carbon atom number of from 1 to 10.

Examples of the substituent of a substituted branched alkyl group or a substituted branched alkylamino group represented by R₁ include a cycloalkyl group (for example, a cyclopentyl group or a cyclohexyl group), an alkenyl group (for example, a vinyl group or a allyl group), an alkinyl group (for example, an ethinyl group or a propargyl group), an aryl group (for example, a phenyl group, or a naphthyl group), a heteroaryl group (for example, a furyl group, a thienyl group, a pyridyl group, a pyridazyl group, a pyrimidyl group, a pyrazyl group, a triazyl group, an imidazolyl group, a pyrazolyl group, a thiazolyl group, a benzimidazolyl group, a benzoxazolyl group, a quinazolyl group, or a phthalazyl group), a saturated heterocyclic group (for example, a pyrrolidyl group, an imidazolidyl group, a morpholyl group or an oxazolidyl group), an alkoxy group (for example, a methoxy group, an ethoxy group, a propoxy group, a pentyloxy group, a hexyloxy group, an octyloxy group, or a dodecyloxy group), a cycloalkoxy group (for example, a cyclopentyloxy group, or a cyclohexyloxy group), an aryloxy group (for example, a phenoxy group or a naphthyloxy group), an alkylthio group (for example, a methylthio group, an ethylthio group, a propylthio group, a pentylthio group, a hexylthio group, an octylthio group, or a dodecylthio group), a cycloalkylthio group (for example, a cyclopentylthio group or a cyclohexylthio group), an arylthio group (for example, a phenylthio group, or a naphthylthio group), an alkoxycarbonyl group (for example, a methyloxycarbonyl group, an ethyloxycarbonyl group, a butyloxycarbonyl group, an octyloxycarbonyl group, or a dodecyloxycarbonyl group), an aryloxycarbonyl group (for example, a phenyloxycarbonyl group, or a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, or a 2-pyridylaminosulfonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecycarbonyl group, a phenylcarbonyl group, a naphthylcarbonyl group, or a pyridylcarbonyl group), an acyloxy group (for example, an acetyloxy group, an ethylcarbonyloxy group, a butylcarbonyloxy group, an octylcarbonyloxy group, a dodecycarbonyloxy group, or a phenylcarbonyloxy group), an amido group (for example, a methylcarbonylamino group, an ethylcarbonylamino group, a dimethylcarbonylamino group, a propylcarbonylamino group, a pentylcarbonylamino group, a cyclohexylcarbonylamino group, 2-ethylhexylcarbonylamino group, an octylcarbonylamino group, a a dodecycarbonylamino group, a phenylcarbonylamino group, or a naphthylcarbonylamino group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecyaminocarbonyl group, a phenylaminocarbonyl group, a naphthylaminocarbonyl group, or a 2-pyridylaminocarbonyl group), a ureido group (for example, a methylureido group, an ethylureido group, a pentylureido group, a cyclohexylureido group, an octylureido group, a dodecylureido group, a phenylureido group, a naphthylureido group, or a 2-pyridylureido group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, or a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, or a dodecylsulfonyl group), an arylsulfonyl group (for example, a phenylsulfonyl group, a naphthylsulfonyl group, or a 2-pyridylsulfonyl group), an amino group (for example, an amino group, an ethylamino group, a dimethylamino group, a butylaminocarbonyl group, a cyclopentylamino group, a 2-ethylhexylamino group, a dodecyamino group, an anilino group, a naphthylamino group, or a 2-pyridylamino group), a halogen atom (for example, fluorine, chlorine, or bromine), a cyano group, a nitro group, and a hydroxyl group. These substituents may have an additional substituent, and the additional substituent is the same as those denoted above.

In R₁ of formula (SF1), the ratio of a total carbon atom number C₂ of the side chains to a total carbon atom number C₁ of the main chain, i., e, C₂/C₁ is preferably from 0.05 to 3.0. R₁ is preferably comprised of a main chain having a carbon atom number of 3 to 19 and at least one side chain having a carbon atom number of 1 to 9.

In formula (SF1), R₂ represents a substituted or unsubstituted alkylene group having a carbon atom number of from 1 to 10.

The substituent of the substituted alkylene group of R₂ is the same as those denoted in the substituted branched alkyl or branched alkylamono group of R₁. Plural R₂s may be the same or different.

In formula (SF1), n represents an integer of 2 to 100.

The HLB value of the surfactant represented by formula (SF1) above is preferably from 11 to 15. The HLB value of not less than 11 renders the surfactant hydrophilic, and improves dispesibility of micelles incorporating a light sensitive material in a developer, while the HLB value of not more than 15 renders the surfactant suitably lipophilic and maintains suitable permeation of a developer into a light sensitive material.

The HLB value herein referred to is a value showing a quantitative measure of the emulsification characteristics of a surfactant and numerically indicates the balance of hydrophilicity and lipophilicity of a surfactant. The HLB value is an abbreviation of the value of hydrophile and lipophile balance.

The HLB value can be determined according to several empirical equations proposed hitherto. The equations are as follows.
(1) HLB of Polyoxyethylene-type Nonionic Surfactant

### (Containing No Other Hydrophilic Group)

HLB=E/5

where E is a polyoxyethylene content (% by weight).
(2) HLB of Ester of Polyhydric Alcohol and Fatty Acid

HLB=20(1−S/A)

where S is a saponification value of ester, and A is an acid value of fatty acid.
(3) HLB of Tall Oil, Pine Oil, Bees Wax and Lanolin Polyhydric Alcohol

HLB=(E+P)/5

where E is oxyethylene content (% by weight), and P is a polyhydric alcohol content (% by weight).
(4) HLB of Silicone-containing Surfactant:

HLB=0.89×(cloud number A)+1.11

where the cloud number (A) can be determined in a manner such that when 0.5 g of a surfactant are dissolved in 5 ml of ethanol to obtain a surfactant ethanol solution and a 2% aqueous phenol solution is dropwise added thereto at 25° C., the milliliter number of the 2% aqueous phenol solution added till the end point when the solution becomes turbid is defined as cloud number A.

The HLB of a mixed surfactant of surfactant “a” exhibiting an HLB value of HLBa and surfactant “b” exhibiting an HLB value of HLBb is represented by the following formula:

HLB={(Wa×HLBa)+(Wb×HLBb)}/(Wa+Wb)

wherein Wa represents a weight fraction of surfactant a, and Wb represents a weight fraction of surfactant b.

In the invention, the HLB value is one calculated from equation (1) above.

Typical examples of compounds represented by formula (SF1) will be listed below, but the invention is not limited thereto.

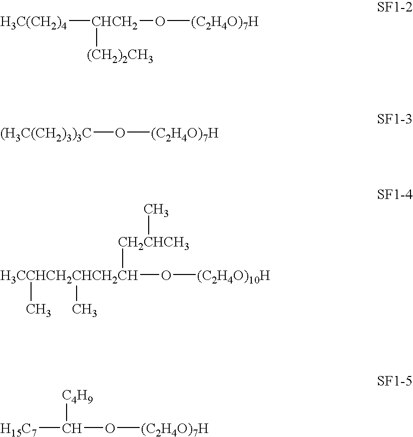

These surfactants are commercially available and can be readily obtained.

### (Compounds Represented by Formula (SF2)

In formula (SF2), R₃ represents an alkyl group having a carbon atom number of from 4 to 10. The alkyl group may be straight-chained, branched or cyclic. A surfactant in which the carbon atom number of R₃ is less than 4 is insufficient in hydrophobic property, and does not function as a surfactant. On the other hand, a surfactant in which the carbon atom number of R₃ is more than 30 is highly hydrophobic, sparingly soluble in water, and cannot be applied to a developer.

In formula (SF2), 1 of the propyleneoxy portion represents an integer of from 1 to 3, and m of the ethyleneoxy portion represents s an integer of from 1 to 100. The ethyleneoxy portions function as a hydrophilic group, and m can be selected so that preferred water solubility is obtained. In the invention, m is preferably from 10 to 50, and more preferably from 10 to 30.

Typical examples of nonionic surfactants represented by formula (SF2) will be listed below, but the invention is not limited thereto.

C₁₀H₂₁O[CH₂CH(CH₃)O]₂(CH₂CH₂O)₁₂H SF2-1:

C₁₀H₂₁O[CH₂CH(CH₃)O]₂(CH₂CH₂O)₁₅H SF2-2:

C₁₀H₂₁O[CH₂CH(CH₃)O]₂(CH₂CH₂O)₂₀H SF2-3:

C₈H₁₇CH(C₁₀H₂₁)CH₂O[CH₂CH(CH₃)O]₂(CH₂CH₂O)₂₀H SF2-4:

C₄H₉CH(C₂H₅)CH₂O[CH₂CH(CH₃)O]₂(CH₂CH₂O)₂₀H SF2-5:

C₁₂H₂₅O[CH₂CH(CH₃)O]₂(CH₂CH₂O)₁₅H SF2-6:

In the invention, besides the above surfactants, various nonionic surfactants can be used in combination. Examples of such nonionic surfactants include polyoxyethylenealkyl ethers, polyoxyethylenealkylphenyl ethers, polyoxyethylene-polystyrylphenyl ethers, polyoxyethylenepolyoxypropylenealkyl ethers, partial esters of glycerin and fatty acids, partial esters of sorbitan and fatty acids, partial esters of pentaerythritol and fatty acids, propylene glycol monofatty acid ester, partial esters of sucrose and fatty acids, partial esters of polyoxyethylenesorbitan and fatty acids, partial esters of polyoxyethylenesorbitol and fatty acids, esters of polyoxyethylene glycol and fatty acids, partial esters of polyglycerin and fatty acids, polyoxyethylene castor oil, partial esters of polyoxyethyleneglycerin and fatty acid, polyoxyethylene-polyoxypropylene block copolymer, an adduct of ethylenediamine and polyoxyethylene-polyoxypropylene block copolymer, fatty acid diethanolamides, N,N-bis-2-hydroxyalkylamines, polyoxyethylenealkylamines, triethanolamine fatty acid esters, and trialkylamine oxides.

### (Co-Initiator)

The light sensitive layer of the light sensitive planographic printing plate material of the invention can contain a conventional co-initiator. In the invention, an especially preferred co-initiator is a tribromoacetamide compound.

Herein, the co-initiator refers to a compound having function promoting polymerization reaction initiated by reaction of a polymerization initiator.

Typical examples of a tribromoacetamide compound used in the invention will be listed below, but the invention is not limited thereto.

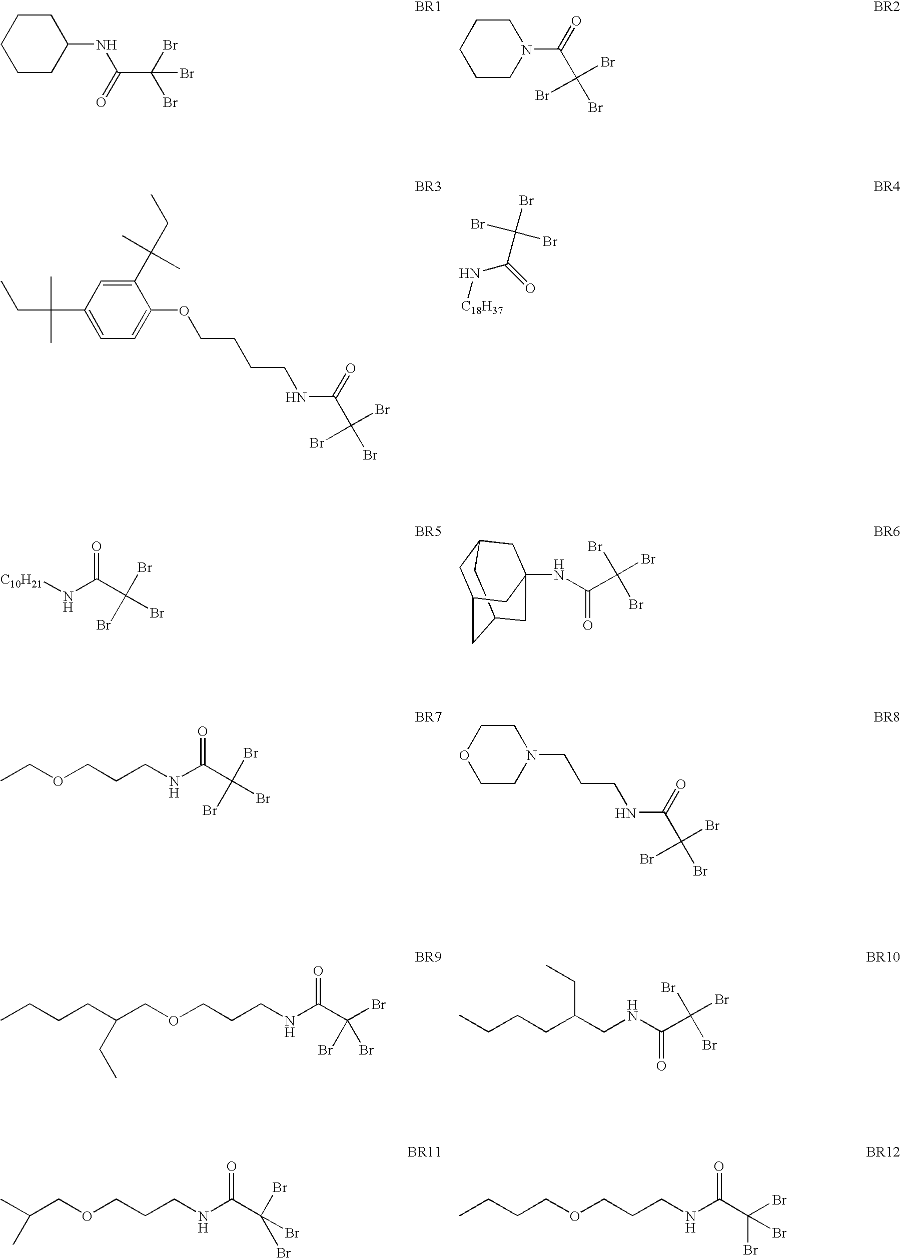

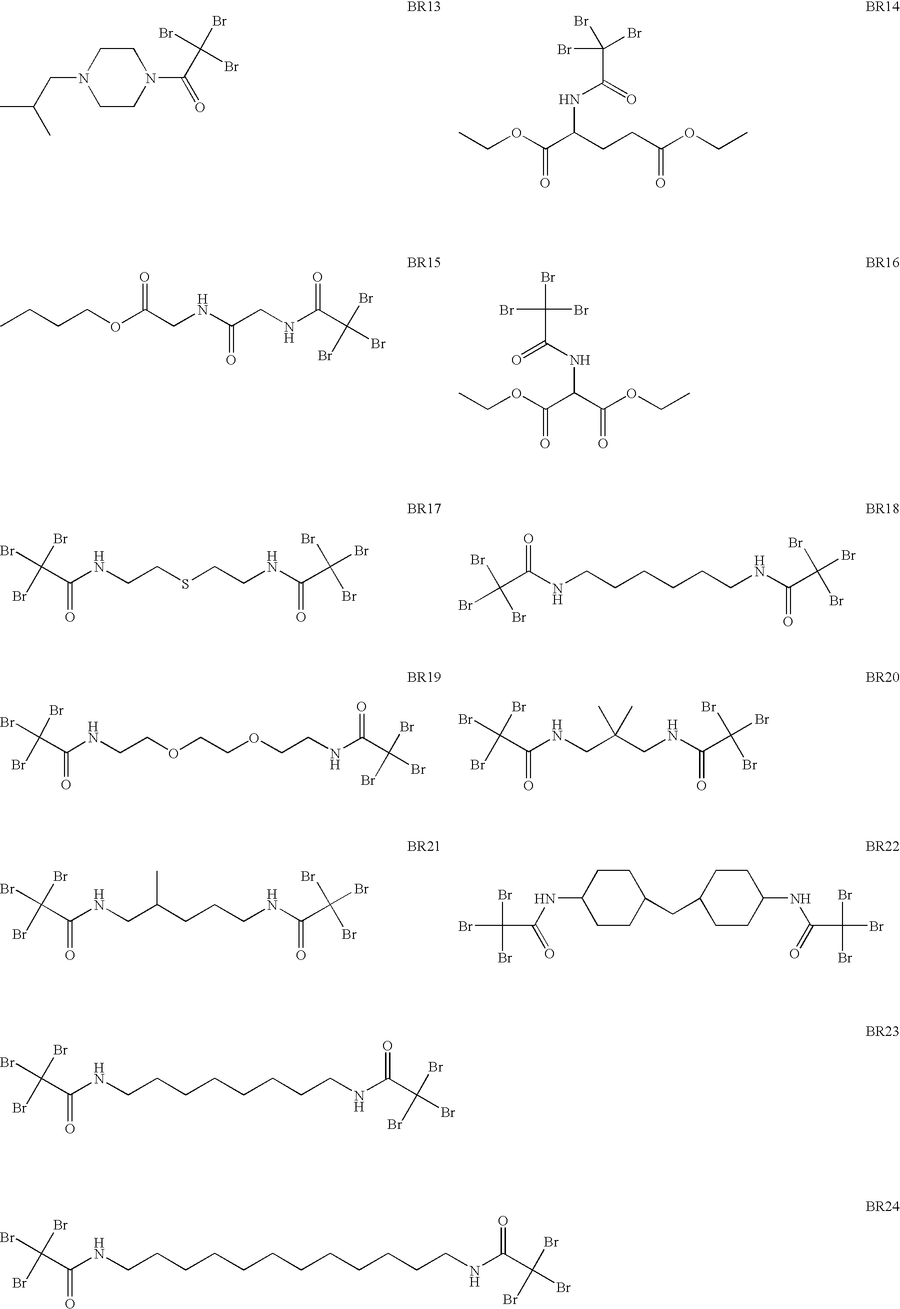

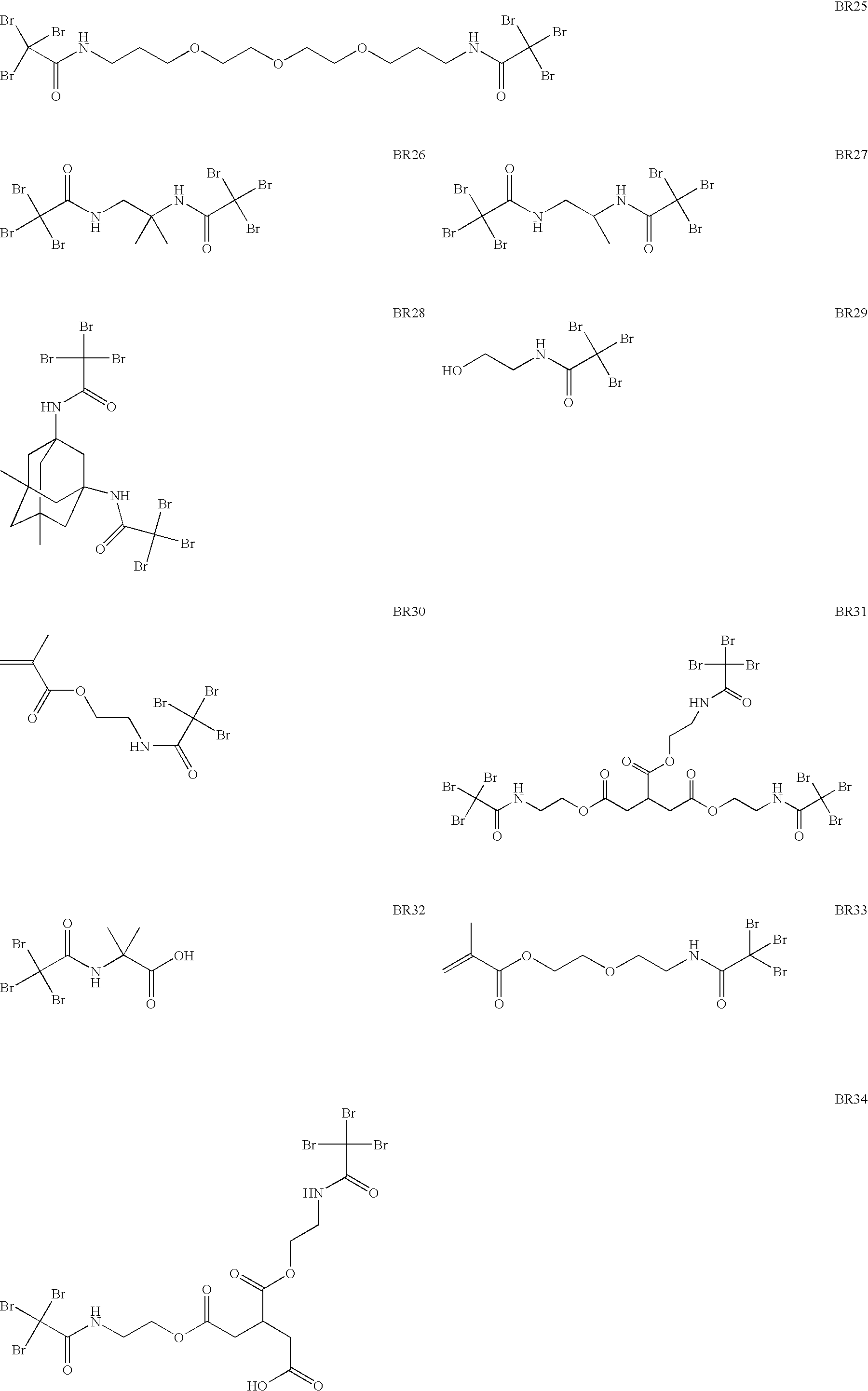

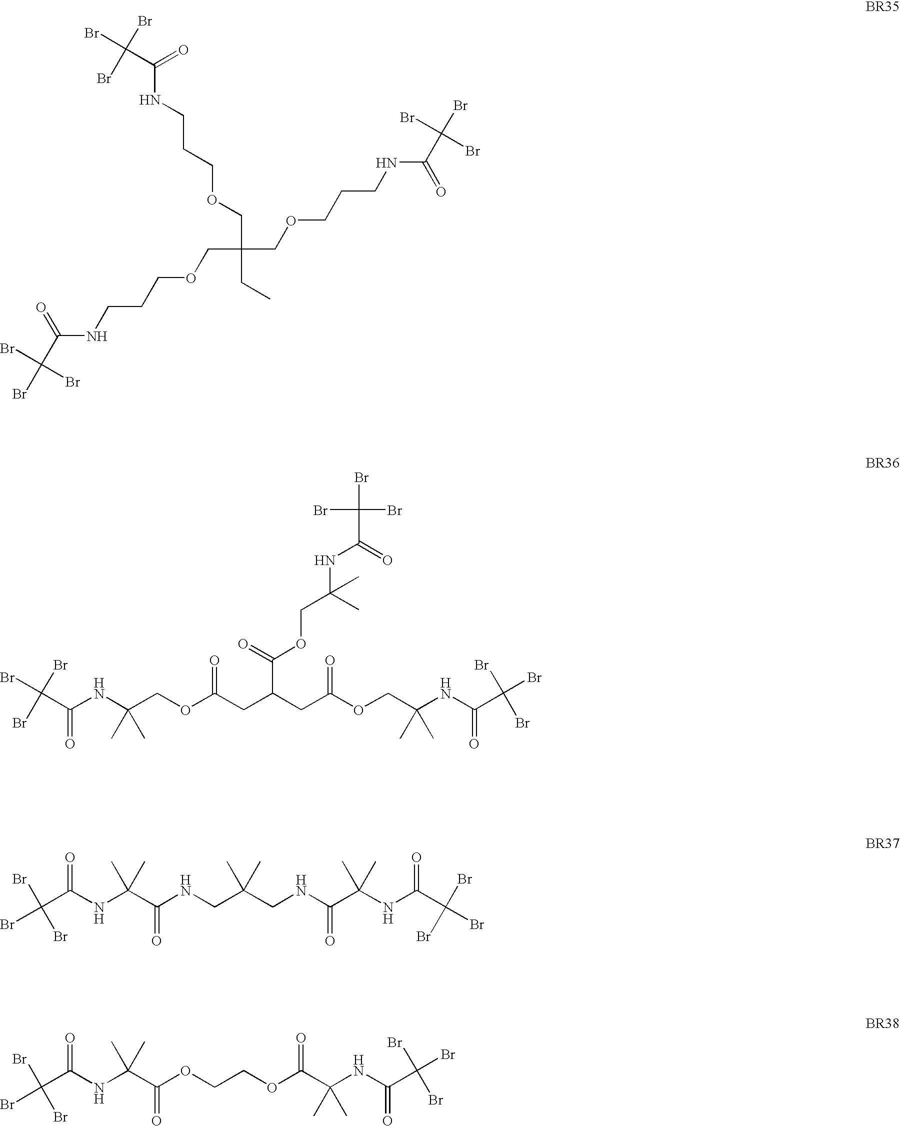

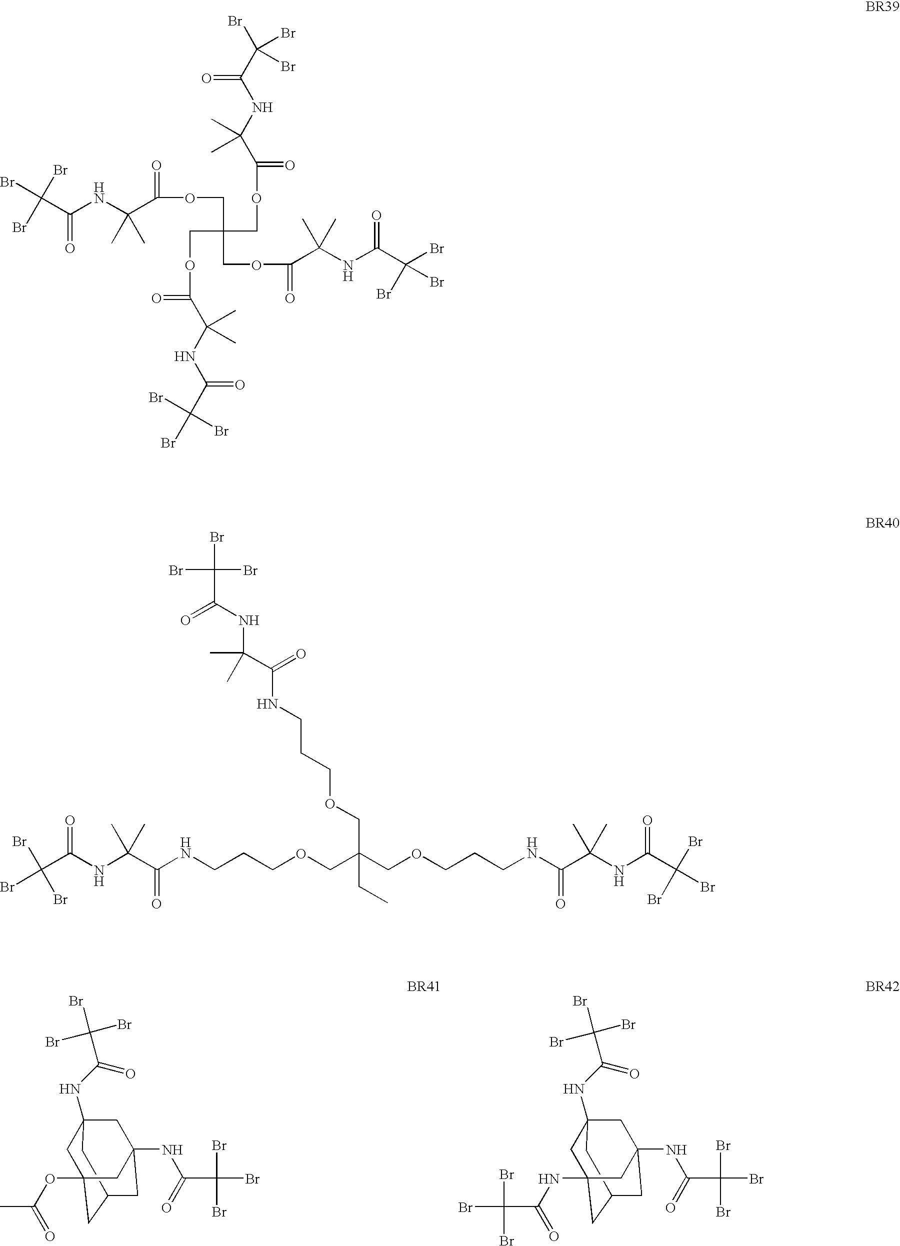

The content of the tribromoacetylamide compound in the light sensitive layer is preferably from 0.01 to 20% by weight, more preferably from 0.1 to 15% by weight, and still more preferably from 1.0 to 10% by weight, based on the total solid content of the light sensitive layer.

In the invention, various conventional co-initiators, for example, co-initiators as disclosed in Japanese Patent O.P.I. Publication Nos. 08-254821 and 2005-062482 can be used.

### (Aqueous Solution for Removing Light Sensitive Layer at Unexposed Portions)

It is preferred in the invention that the manufacturing process of a planographic printing plate comprises the steps of imagewise exposing a light sensitive planographic printing plate material, employing a laser, and removing a light sensitive layer at unexposed portions (non-image portions) at 25° C. with an aqueous solution with a pH of 3.0 to 9.0 containing a water soluble resin and a surfactant. The upper pH in the above pH range can shorten time for removing a light sensitive layer at unexposed portions, without lowering sensitivity and image quality.

The aqueous solution can contain the surfactants described later. It is preferred that the aqueous solution can contain the surfactant represented by formula (SF1) or (SF2) above.

Examples of the water soluble resin include gum arabic, starch, starch derivatives, dextrin, white dextrin, cellulose derivatives (e.g., carboxymethyl cellulose, carboxymethyl cellulose, methyl cellulose) and their modified compounds, polyvinyl alcohol and its derivatives, polyvinyl pyrrolidone, polyacrylamide and its copolymers, poly[(vinyl methyl ether)-co-(anhydrous maleic acid)], poly[(vinyl acetate)-co-(anhydrous maleic acid)], and poly[styrene-co-(anhydrous maleic acid)]. The content of the water soluble resin in the aqueous solution is preferably 0.1 to 30% by weight, and more preferably from 0.5 to 10% by weight.

Besides the surfactant represented by formula (SF1) or (SF2), the aqueous solution in the invention can contain various anionic and/or nonionic surfactants. For example, as the anionic surfactants, there are mentioned fatty acid salts, abietic acid salts, hydroxyalkane sulfonic acid salts, alkane sulfonic acid salts, dialkylsulfosuccinic acid salts, straight-chained alkylbenzene sulfonic acid salts, branched alkylbenzene sulfonic acid salts, alkylnaphthalene sulfonic acid salts, alkylphenoxypolyoxyethylenepropyl sulfonic acid salts, polyoxyethylenealkyl sulfophenylether salts, N-methyl-N-oleiltaurine sodium salts, N-alkylsulfosuccinic acid monoamide disodium salts, petroleum sulfonic acid salts, nitrated castor oil, sulfated beef tallow, fatty acid alkyl ester sulfate salts, alkylsulfate salts, polyoxyethylenealkylethersulfate salts, fatty acid monoglyceride sulfate salts, polyoxyethylenealkylphenylethersulfate salts, polyoxyethylenestyrylphenylethersulfate salts, alkylphosphate salts, polyoxyethylenealklyletherphosphate salts, polyoxyethylenealkylphenyletherphosphate salts, partial saponification products of styrene-maleic anhydride copolymers, partial saponification products of olefin-maleic anhydride copolymers, and condensates of naphthalene sulfonic acid salts with formalin. Among these, dialkylsulfosuccinic acid salts, alkylsulfate salts and allkylnaphthalene sulfonic acid salts are preferably used.

As the nonnionic surfactants, there are mentioned polyoxyethylenealkyl ethers, polyoxyethylenealkylphenyl ethers, polyoxyethylenearyl ethers, polyoxyethylenenaphthyl ethers, polyoxyethylene-polystyrylphenyl ethers, polyoxyethylenepolyoxypropylenalkyl ethers, partial esters of glycerin and fatty acids, partial esters of sorbitan and fatty acids, partial esters of pentaerythritol and fatty acids, propylene glycol monofatty acid ester, partial esters of sucrose and fatty acids, partial esters of polyoxyethylenesorbitan and fatty acids, partial esters of polyoxyethylenesorbitol and fatty acids, esters of polyoxyethylene glycol and fatty acids, partial esters of polyglycerin and fatty acids, polyoxyethylene castor oil, partial esters of polyoxyethyleneglycerin and fatty acid, diethanolamides, N,N-bis-2-hydroxyalkylamines, polyoxyethylenealkylamines, triethanolamine fatty acid esters, and trialkylamine oxides. Among these, polyoxyethylenealkylphenyl ethers, polyoxyethylenepolyoxypropylenalkyl ethers, and polyoxyethylene-polyoxypropylene block copolymer are preferably used.

Further, fluorine-containing or silicon-containing anionic surfactants or fluorine-containing or silicon-containing nonionic surfactants can be used.

As the preferred surfactants, there are mentioned surfactants as disclosed in Japanese Patent O.P.I. Publication Nos. 2004-167903 and 2004-230650 and 2005-43393, which are added in the protective solution.

These surfactants can be used as an admixture of two or more kinds thereof. For example, a combined use of two or more different anionic surfactants or a combined use of an anionic surfactant and a nonionic surfactant is preferred. The amount of the surfactant in the aqueous solution in the invention is not specifically limited, but it is preferably 0.01 to 20% by weight. The surfactant represented by formula (SF1) or (SF2) is preferably used in that amount.

The aqueous solution in the invention is used within the range of a pH of 3.0 to 9.0. When the pH is adjusted to the range of 3 to 6, acids such as mineral acids, organic acids or inorganic salts are added to the aqueous solution. The addition amount of the acid is preferably in the range of 0.01 to 2% by weight. The mineral acids include, for example, nitric acid, sulfuric acid, phosphoric acid and metaphosphoric acid.

The organic acids include, for example, citric acid, acetic acid, oxalic acid, malonic acid, p-toluenesulfonic acid, tartaric acid, malic acid, lactic acid, levulinic acid, phytic acid and organic phosphonic acid.

The inorganic salts include, for example, magnesium nitrate, primary phosphate, secondary phosphate, nickel sulfate, sodium hexamethanate, and sodium tripolyphosphate. The mineral acids, organic acids and inorganic salts may be used alone or as a mixture of two or more kinds thereof.

When the aqueous solution within the basic range of a pH of 8 to 9 is used, water soluble organic or inorganic bases are added to the solution. Preferred examples of the water soluble organic bases include triethanolamine, diethanolamine and ethanolamine.

The aqueous solution in the invention may be added with antiseptics or defoaming agents. Examples of the antiseptics include phenol and its derivatives, formaline, imidazole derivatives, sodium dehydroacetate, 4-isothiazoline-3-one derivatives, benzoisothiazoline-3-one, benzotriazole derivatives, amidinoguanine derivatives, quaternary ammonium salts, derivatives of pyridine, quinoline and guanine, diazine, triazole derivatives, oxazole, and oxazine derivatives. A preferred content is a quantity capable of taking stable effect upon bacteria, mold or yeast, depending on the kind of bacteria, molds or yeast. The content is preferably 0.01 to 4% by weight, based on the working gum solution. Two or more antiseptic are preferably used as a mixture of two or more kinds thereof to take effects upon various kinds of bacteria or molds. Silicone defoaming agents are preferred, and any one of emulsion type and solubilization type is usable. A defoaming agent is used suitably at 0.01 to 1.0% by weight, based on the gum solution used.

Further, there may be added chelating agents. Preferred chelating agents include, for example, ethylenediaminetetraacetic acid and its sodium and potassium salts, diethylenetriaminepentaacetic acid and its sodium and potassium salts, triethylenetetraminehexaacetic acid and its sodium and potassium salts, ethylenediaminedisuccinic acid and its sodium and potassium salts, hydroxyethylethylenediaminetriacetic acid and its sodium and potassium salts, nitrilotriacetic acid and its sodium and potassium salts, and organic phosphonic acids or phosphonoalkanecarboxylic acids, such as 1-hydroxyethane-1,1-diphosphonic acid and its sodium and potassium salts, aminotri(methylenephosphonic acid) and its sodium and potassium salts. Besides the foregoing sodium and potassium salts of chelating agents, organic amine salts are also effective. Chelating agents are selected from those which can be stably present in the gum solution composition and is free from adverse effects on printing. The content thereof is preferably 0.001 to 1.0% by weight, based on the gum solution used.

In addition to the above ingredients, a lipophilicity-enhancing agent may be incorporated. Examples thereof include hydrocarbons such as turpentine oil, xylene, toluene, low heptane, solvent naphtha, kerosene, mineral spirit, petroleum fractions exhibiting a boiling point of ca. 120 to 250° C.; and plasticizers exhibiting a freezing point of 15° C. or less and a boiling point of 300° C. or more at 1 atmospheric pressure, including phthalic acid diesters such as dibutyl phthalate, diheptyl phthalate, di-n-octyl phthalate, di(2-ethylhexyl)phthalate, dinonyl phthalate, didecyl phthalate, dilauryl phthalate, and butylbenzyl phthalate; dibasic fatty acid esters, such as dioctyl adipate, butylglycol adipate, dioctyl azelate, dibutyl sebacate, di(2-ethylhexyl)sebacate, and diocyl sebacate; epoxy-modified triglycerides such as epoxy-modified soybean oil; phosphoric acid esters such as tricresyl phosphate, trioctyl phosphate, and triscrolethyl phosphate; and benzoic acid esters such as benzyl benzoate.

Further, there are included saturated fatty acids such as caproic acid, enatoic acid, heralgonic acid, capric acid, undecylic acid, lauric acid, tridecylic acid, myristic acid, pentadecylic acid, palmitic acid, heptadecylic acid, stearic acid, nonadecanoic acid, arachic acid, behenic acid, lignoceric acid, cerotic acid, heptacosanoic acid, montanic acid, melissic acid, lacceric acid, and iso-valeric acid; and unsaturated fatty acids such as acrylic acid, crotonic acid, isocrotonic acid, undecylenic acidpleic acid, elaidic acid, cetoleic acid, nilcaic acid, btecidinic acid, sorbic acid, linolic acid, linolenic acid, arachidonic acid, propiolic acid, stearolic acid, sardine oil, tariric acid, and licanic acid. Of the foregoing, a fatty acid which is liquid at 50° C. is more preferred, one having 5 to 25 carbons is still more preferred, and one having 8 to 21 carbons is most preferred. These lipophilicity-enhancing agents may be used alone or as a mixture of two or more kinds thereof. The content thereof is preferably 0.01 to 10%, and more preferably 0.05 to 5% by weight, based on the solution.

The light sensitive planographic printing plate material of the invention is preferably one such that after it is imagewise exposed employing a laser with an emission wavelength of from 350 to 450 nm, a light sensitive layer at unexposed portions is removed with an aqueous solution with a pH at 25° C. Of 3.0 to 9.0 containing a water soluble resin and a surfactant. As methods for easily removing the light sensitive layer at unexposed portions, there are various methods.

One of the methods is a method, which appropriately selects kinds or content of a polymerizable monomer to be incorporated in the light sensitive layer, so that the light sensitive layer at unexposed portions is easily removed. For example, use of a polymerizable monomer having in the molecule a hydroxyl group or a N-vinyl pyrrolidone homo-polymer or copolymer as a polymeric binder is preferred in solving the problems described previously.

As another method for removing a light sensitive layer at unexposed portions, there is a method which comprises the steps of (a) imagewise exposing a light sensitive planographic printing plate material, employing a laser, (b) heating the exposed light sensitive planographic printing plate material so that the surface temperature of the exposed material is from 80 to 160° C., and (c) removing the light sensitive layer at unexposed portions with the aqueous solution; or a method which comprises, between the steps (b) and (c) above, the step of removing an oxygen shielding layer and a part of the light sensitive layer with washing water, each being also preferred in solving the problems described previously.

### (Polymerization Initiator)

The polymerization initiator in the invention is a compound which initiates polymerization of a polymerizable monomer such as an ethylenically unsaturated compound on light exposure. In the invention, various conventional polymerization initiators can be used.

In the invention, an iron arene complex or a biimidazole compound is preferably used. Besides these initiators, a titanocene compound, a monoallyltriaryl borate compound or a polyhalogenated compound can be used in combination.

### <Iron Arene Complex>

The iron arene complex used in the invention is a compound represented by formula (a) below.

(A-Fe—B)⁺X³¹ Formula (a)

wherein A represents a substituted or unsubstituted cyclopentadienyl group or a substituted or unsubstituted cyclohexadienyl group; B represents a compound having an aromatic ring; and X⁻ is an anion.

Examples of the compound having an aromatic ring include benzene, toluene, xylene, cumene, naphthalene, 1-methylnaphtalene, 2-methylnaphtalene, biphenyl, fluorene, anthracene and pyrene. Examples of X⁻ include PF₆⁻, BF₄⁻, SbF₆⁻, AlF₄⁻, and CF₃SO₃⁻. The substituents of the substituted or unsubstituted cyclopentadienyl group or a substituted or unsubstituted cyclohexadienyl group include an alkyl group such as methyl, ethyl, etc., a cyano group, an acetyl group and a halogen atom.

Examples of the iron arene complex include:
Fe-1: (η6-benzene)(η5-cyclopentadienyl)iron (2) hexafluorophosphate;
Fe-2: (η6-toluene)(η5-cyclopentadienyl)iron (2) hexafluorophosphate;
Fe-3: (η6-cumene)(η5-cyclopentadienyl)iron (2) hexafluorophosphate;
Fe-4: (η6-benzene)(η5-cyclopentadienyl)iron (2) hexafluoroarsenate;
Fe-6: (η6-benzene)(η5-cyclopentadienyl)iron (2) tetrafluoroborate;
Fe-6: (η6-naphthalene)(η5-cyclopentadienyl)iron (2) hexafluorophosphate;
Fe-7: (η6-anthracene)(η5-cyclopentadienyl)iron (2) hexafluorophosphate;
Fe-8: (η6-pyrene) (η5-cyclopentadienyl)iron (2) hexafluorophosphate;
Fe-9: (η6-benzene)(η5-cyanocyclopentadienyl)iron (2) hexafluorophosphate;
Fe-10: (η6-toluene)(η5-acetylcyclopentadienyl)iron (2) hexafluorophosphate;
Fe-11: (η6-cumene) (η5-cyclopentadienyl)iron (2) tetrafluoroborate;
Fe-12: (η6-benzene)(η5-carboethoxycyclohexadienyl)iron (2) hexafluorophosphate;
Fe-13: (η6-benzene)(η5-1,3-dichlorocyclohexadienyl)iron (2) hexafluorophosphate;
Fe-14: (η6-cyanobenzene)(η5-cyclohexadienyl)iron (2) hexafluorophosphate;
Fe-15: (η6-acetophenone)(η5-cyclohexadienyl)iron (2) hexafluorophosphate;
Fe-16: (η6-methyl benzoate)(η5-cyclopentadienyl)iron (2) hexafluorophosphate;
Fe-17: (η6-benzene sulfonamide)(η5-cyclopentadienyl)iron (2) tetrafluoroborate;
Fe-18: (η6-benzamide)(η5-cyclopentadienyl)iron (2) hexafluorophosphate;
Fe-19: (η6-cyanobenzene)(η5-cyanocyclopentadienyl)iron (2) hexafluorophosphate;
Fe-20: (η6-chloronaphthalene)(η5-cyclopentiadienyl)iron (2) hexafluorophosphate;
Fe-21: (η6-anthracene)(η5-cyanocyclopentadienyl)iron (2) hexafluorophosphate;
Fe-22: (η6-chlorobenzene)(η5-cyclopentadienyl)iron (2) hexafluorophosphate; and
Fe-23: (η6-chlorobenzene)(η5-cyclopentadienyl)iron (2) tetrafluoroborate.

These compounds can be synthesized according to a method described in Dokl. Akd. Nauk. SSSR 149 615(1963).

### <Biimidazole Compound>

The biimidazole compound used in the invention is a derivative of biimidazole, and examples thereof include those disclosed in for example, Japanese Patent O.P.I. Publication No. 2003-295426. In the invention, a hexaarylbiimidazole (HABI, a dimer of a triarylimidazole) is preferred as the biimidazole compound. The synthetic method of the hexaarylbiimidazole (HABI, a dimer of triarylimidazole) is disclosed in DE 1470154, and use thereof in a photopolymerizable composition is disclosed in EP 24629, EP 107792, U.S. Pat. No. 4,410,621, EP 215453 and DE 321312.

Preferred examples of the biimidazole compound include 2,4,5,2′,4′,5′-hexaphenylbiimidazole, 2,2′-bis(2-chlorophenyl)-4,5,4′,5′-tetraphenylbiimidazole, 2,2′-bis(2-bromophenyl)-4,5,4′,5′-tetraphenylbiimidazole, 2,2′-bis(2,4-dichlorophenyl)-4,5,4′,5′-tetraphenyl-biimidazole, 2,2′-bis(2-chlorophenyl)-4,5,4′,5′-tetrakis(3-methoxyphenyl)biimidazole, 2,2′-bis(2-chlorophenyl)-4,5,4′,5′-tetrakis-(3,4,5-trimethoxyphenyl)biimidazole, 2,5,2′,5′-tetrakis(2-chlorophenyl)-4,4′-bis(3,4-dimethoxyphenyl)biimidazole, 2,2′-bis(2,6-dichlorophenyl)-4,5,4′,5′-tetraphenylbiimidazole, 2,2′-bis(2-nitrophenyl)-4,5,4′,5′-tetraphenylbiimidazole, 2,2′-di-o-tolyl-4,5,4′,5′-tetraphenylbiimidazole, 2,2′-bis(2-ethoxyphenyl)-4,5,4′,5′-tetraphenylbiimidazole, and 2,2′-bis(2,6-difluorophenyl)-4,5,4′,5′-tetraphenylbiimidazole.

### <Titanocene Compound>

The titanocene compounds are described in Japanese Patent O.P.I. Publication Nos. 63-41483 and 2-291. Preferred examples of the titanocene compounds include bis(cyclopentadienyl)-Ti-di-chloride, bis(cyclopentadienyl)-Ti-bis-phenyl, bis(cyclopentadienyl)-Ti-bis-2,3,4,5,6-pentafurophenyl, bis(cyclopentadienyl)-Ti-bis-2,3,5,6-tetrafluorophenyl, bis(cyclopentadienyl)-Ti-bis-2,4,6-trifluorophenyl, bis(cyclopentadienyl)-Ti-bis-2,6-difluorophenyl, bis(cyclopentadienyl)-Ti-bis-2,4-difluorophenyl, bis(methylcyclopentadienyl)-Ti-bis-2,3,4,5,6-pentafluorophenyl, bis(methylcyclopentadienyl)-Ti-bis-2,3,5,6-tetrafluorophenyl, bis(methylcyclopentadienyl)-Ti-bis-2,6-difluorophenyl (IRUGACURE 784, produced by Ciba Speciality Chemicals Co.), bis(cyclopentadienyl)-bis(2,4,6-trifluoro-3-(pyry-1-yl)phenyl)titanium, and bis(cyclopentadienyl)-bis(2,4,6-trifluoro-3-(2-5-dimethylpyry-1-yl)phenyl)titanium.

### <Monoalkyltriaryl Borate Compound>

As the monoalkyltriaryl borate compound, there are those described in Japanese Patent O.P.I. Publication Nos. 62-150242 and 62-143044. Preferred examples of the monoalkyl-triaryl borate compounds include tetra-n-butyl ammonium n-butyltrinaphthalene-1-yl-borate, tetra-n-butylammonium n-butyltriphenylborate, tetra-n-butylainmonium triphenyl-mono-t-butylborate, tetra-n-butylammoniuin n-butyl-tri-(4-tert-butylphenyl)borate, tetra-n-butylammonium n-hexyl-tri-(3-chloro-4-methylphenyl)borate, and tetra-n-butylammonium n-hexyl-tri-(3-fluorophenyl)borate.

### <Polyhalogenated Compound>

As the polyhalogenated compound, a compound having a trihalomethyl group, a dihalomethyl group or a dihalomethylene group is preferably used. In the invention, an oxadiazole compound having in the molecule the group described above as the substituent or a polyhalogenated compound represented by the following formula (PIH1) is preferably used.

A polyhalogenated compound represented by the following formula (PIH2) is especially preferably used.

R¹—C(Y)₂—(C═O)—R² Formula (PIH1)

wherein R¹ represents a hydrogen atom, a halogen atom, an alkyl group, an aryl group, an acyl group, an alkylsulfonyl group, an arylsulfonyl group, an iminosulfo group or a cyano group; R² represents a monovalent substituent, provided that R¹ and R² may combine with each other to form a ring; and Y represents a halogen atom.

C(Y)₃—(C═O)—X—R³ Formula (PIH2)

wherein R³ represents a monovalent substituent; X represents —O— or —NR⁴— in which R⁴ represents a hydrogen atom or an alkyl group, provided that when X represents —NR⁴—, R³ and R⁴ may combine with each other to form a ring; and Y represents a halogen atom.

Among these, a polyhalogenated compound having a polyhaloacetylamide group is preferably used.

An oxadiazole compound having a polyhalomethyl group as the substituent also is preferably used. Further, oxadiazole compounds disclosed in Japanese Patent O.P.I. Publication Nos. 5-34904 and 8-240909 are preferably used.

Another photopolymerization initiator can be used in combination. Examples thereof include carbonyl compounds, organic sulfur compounds, peroxides, redox compounds, azo or diazo compounds, halides and photo-reducing dyes disclosed in J. Kosar, “Light Sensitive Systems”, Paragraph 5, and those disclosed in British Patent No. 1,459,563.

Typical examples of the photopolymerization initiator used in combination include the following compounds:

A benzoin derivative such as benzoin methyl ether, benzoin i-propyl ether, or α,α-dimethoxy-α-phenylacetophenone; a benzophenone derivative such as benzophenone, 2,4-dichlorobenzophenone, o-benzoyl methyl benzoate, or 4,4′-bis(dimethylamino)benzophenone; a thioxanthone derivative such as 2-chlorothioxanthone, 2-i-propylthioxanthone; an anthraquinone derivative such as 2-chloroanthraquinone or 2-methylanthraquinone; an acridone derivative such as N-methylacridone or N-butylacridone; α,α-diethoxyacetophenone; benzil; fluorenone; xanthone; an uranyl compound; a triazine derivative disclosed in Japanese Patent Publication Nos. 59-1281 and 61-9621 and Japanese Patent O.P.I. Publication No. 60-60104; an organic peroxide compound disclosed in Japanese Patent O.P.I. Publication Nos. 59-1504 and 61-243807; a diazonium compound in Japanese Patent Publication Nos. 43-23684, 44-6413, 47-1604 and U.S. Pat. No. 3,567,453; an organic azide compound disclosed in U.S. Pat. Nos. 2,848,328, 2,852,379 and 2,940,853; orthoquinondiazide compounds disclosed in Japanese Patent Publication Nos. 36-22062b, 37-13109, 38-18015 and 45-9610; various onium compounds disclosed in Japanese Patent Publication No. 55-39162, Japanese Patent O.P.I. Publication No. 59-14023 and “Macromolecules”, Volume 10, p. 1307 (1977); azo compounds disclosed in Japanese Patent Publication No. 59-142205; metal arene complexes disclosed in Japanese Patent O.P.I. Publication No. 1-54440, European Patent Nos. 109,851 and 126,712, and “Journal of Imaging Science”, Volume 30, p. 174 (1986); (oxo) sulfonium organoboron complexes disclosed in Japanese Patent O.P.I. Publication Nos. 5-213861 and 5-255347; titanocenes disclosed in Japanese Patent O.P.I. Publication Nos. 59-152396 and 61-151197; transition metal complexes containing a transition metal such as ruthenium disclosed in “Coordination Chemistry Review”, Volume 84, p. 85-277 (1988) and Japanese Patent O.P.I. Publication No. 2-182701; 2,4,5-triarylimidazol dimmer disclosed in Japanese Patent O.P.I. Publication No. 3-209477; carbon tetrabromide; organic halide compounds disclosed in Japanese Patent O.P.I. Publication No. 59-107344.

The content of the polymerization initiator in the light sensitive layer is preferably from 0.1 to 20% by weight, and more preferably from 0.5 to 15% by weight, based on the total content of polymerizable compound.

### (Polymerizable Monomer)

The polymerizable monomer is a compound capable of polymerizing by a reaction product of a polymerization initiator produced on imagewise exposure. As the polymerizable monomer, a wide range of compounds can be used which are capable of initiating polymerization by reaction with radicals generated from the polymerization initiator in the invention.

As the polymerizable monomer in the invention, ethylenically unsaturated compound is preferably used. Examples of the ethylenically unsaturated compound include conventional radically polymerizable monomers, and polyfunctional monomers and polyfunctional oligomers each having plural ethylenically unsaturated bond ordinarily used in UV-curable resins.

The polymerizable monomer in the invention is not specifically limited, but preferred examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryloxyethyl acrylate, tetrahydrofurfuryloxyhexyl acrylate, or 1,3-dioxolanyl acrylate; a methacrylate, itaconate, crotonate or maleate alternative of the above acrylate; a bifunctional acrylate such as ethyleneglycol diacrylate, triethyleneglycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-s-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-ε-caprolactone adduct or 1,6-hexanediol diglycidylether diacrylate; a dimethacrylate, diitaconate, dicrotonate or dimaleate alternative of the above diacrylate; a polyfunctional acrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-.ε-caprolactone adduct, pyrrogallol triacrylate, propionic acid dipentaerythritol triacrylate, propionic acid dipentaerythritol tetraacrylate, hydroxypivalylaldehyde modified dimethylolpropane triacrylate or EO-modified products thereof; and a methacrylate, itaconate, crotonate or maleate alternative of the above polyfunctional acrylate.

A prepolymer can be used as the polymerizable monomer described above. Examples of the prepolymer include compounds described later and prepolymers with a photopolymerization property obtained by incorporating an acryloyl or methacryloyl group into a prepolymer with an appropriate molecular weight. These prepolymers can be used singly or as an admixture of the above described monomers and/or oligomers.

Examples of the prepolymer include polyester (meth)acrylate obtained by incorporating (meth)acrylic acid in a polyester of a polybasic acid such as adipic acid, trimellitic acid, maleic acid, phthalic acid, terephthalic acid, hymic acid, malonic acid, succinic acid, glutaric acid, itaconic acid, pyromellitic acid, fumalic acid, pimelic acid, sebatic acid, dodecanic acid or tetrahydrophthalic acid with a polyol such as ethylene glycol, ethylene glycol, diethylene glycol, propylene oxide, 1,4-butane diol, triethylene glycol, tetraethylene glycol, polyethylene glycol, grycerin, trimethylol propane, pentaerythritol, sorbitol, 1,6-hexanediol or 1,2,6-hexanetriol; an epoxyacrylate such as bisphenol A.epichlorhydrin.(meth)acrylic acid or phenol novolak.epichlorhydrin.(meth)acrylic acid obtained by incorporating (meth)acrylic acid in an epoxy resin; an urethaneacrylate such as ethylene glycol.adipic acid.tolylenediisocyanate.2-hydroxyethylacrylate, polyethylene glycol.tolylenediisocyanate.2-hydroxyethylacrylate, hydroxyethylphthalyl methacrylate.xylenediisocyanate, 1,2-polybutadieneglycol.tolylenediisocyanate. 2-hyroxyethylacrylate or trimethylolpropane.propylene glycol.tolylenediisocyanate.2-hydroxyethylacrylate, obtained by incorporating (meth)acrylic acid in an urethane resin; a silicone acrylate such as polysiloxane acrylate, or polysiloxane.diisocyanate.2-hydroxyethylacrylate; an alkyd modified acrylate obtained by incorporating a methacroyl group in an oil modified alkyd resin; and a spiran resin acrylate.

The light sensitive layer can contain a monomer such as a phosphazene monomer, triethylene glycol, an EO modified isocyanuric acid diacrylate, an EO modified isocyanuric acid triacrylate, dimethyloltricyclodecane diacrylate, trimethylolpropane acrylate benzoate, an alkylene glycol acrylate, or a urethane modified acrylate, or an addition polymerizable oligomer or prepolymer having a structural unit derived from the above monomer.

As the ethylenically unsaturated compound used in combination in the light sensitive layer, there is a phosphate compound having at least one (meth)acryloyl group. The phosphate compound is a compound having a (meth)acryloyl group in which at least one hydroxyl group of phosphoric acid is esterified, but is not limited as long as it has a (meth)acryloyl group.

Besides the above compounds, compounds disclosed in Japanese Patent O.P.I. Publication Nos. 58-212994, 61-6649, 62-46688, 62-48589, 62-173295, 62-187092, 63-67189, and 1-244891, compounds described on pages 286 to 294 of “11290 Chemical Compounds” edited by Kagakukogyo Nipposha, and compounds described on pages 11 to 65 of “UV.EB Koka Handbook (Materials)” edited by Kobunshi Kankcokai can be suitably used. Of these compounds, compounds having two or more acryl or methacryl groups in the molecule are preferable, and those having a molecular weight of not more than 10,000, and preferably not more than 5,000 are more preferable.

It is preferred in the invention that the light sensitive layer contains a tertiary amine monomer, an ethylenically unsaturated compound having a tertiary amino group in the molecule. The monomer is not specifically limited to the chemical structure, but is preferably a hydroxyl group-containing tertiary amine modified with glycidyl methacrylate, methacrylic acid chloride or acrylic acid chloride. Typically, a polymerizable compound is preferably used which is disclosed in Japanese Patent O.P.I. Publication Nos. 1-165613, 1-203413 and 1-197213.

In the invention, a reaction product of a polyhydric alcohol having a tertiary amino group in the molecule, a diisocyanate, and a compound having both a hydroxyl group and an addition polymerizable ethylenically double bond in the molecule is preferably used. A compound having a tertiary amino group and an amide bond in the molecule is especially preferred.

Examples of the polyhydric alcohol having a tertiary amino group in the molecule include triethanolamine, N-methyldiethanolamine, N-ethyldiethanolamine, N-ethyldiethanolamine, N-n-butyldiethanolamine, N-tert-butyldiethanolamine, N,N-di(hydroxyethyl)aniline, N,N,N′,N′-tetra-2-hydroxypropylethylenediamine, p-tolyldiethanolamine, N,N,N′,N′-tetra-2-hydroxyethylethylenediamine, N,N-bis(2-hydroxypropyl)aniline, allyldiethanolamine, 3-dimethylamino-1,2-propane diol, 3-diethylamino-1,2-propane diol, N,N-di(n-propylamino)-2,3-propane diol, N,N-di(iso-propylamino)-2,3-propane diol, and 3-(N-methyl-N-benzylamino)-1,2-propane diol, but the invention is not specifically limited thereto.

Examples of the diisocyanate include butane-1,4-diisocyanate, hexane-1,6-diisocyanate, 2-methylpentane-1,5-diisocyanate, octane-1,8-diisocyanate, 1,3-diisocyanatomethylcyclohexanone, 2,2,4-trimethylhexane-1,6-diisocyanate, isophorone diisocyanate, 1,2-phenylene diisocyanate, 1,3-phenylene diisocyanate, 1,4-phenylene diisocyanate, tolylene-2,4-diisocyanate, tolylene-2,5-diisocyanate, tolylene-2,6-diisocyanate, 1,3-di(isocyanatomethyl)benzene, and 1,3-bis(1-isocyanato-1-methylethyl)benzene, but the invention is not specifically limited thereto.

Examples of the compound having a hydroxyl group and an addition polymerizable ethylenically double bond in the molecule is not specifically limited, but 2-hydroxyethyl methacrylate (MH-1), 2-hydroxyethyl acrylate (MH-2), 4-hydroxybutyl acrylate (MH-4), 2-hydroxypropylene-1,3-dimethacrylate (MH-7), and 2-hydroxypropylene-1-methacrylate-3-acrylate (MH-8) are preferred.

Examples of the reaction product of a polyhydric alcohol having a tertiary amino group in the molecule, a diisocyanate, and a compound having a hydroxyl group and an addition polymerizable ethylenically double bond in the molecule will be listed below.

The reaction product can be synthesized according to the same method as a conventional method in which a urethaneacrylate compound is ordinarily synthesized employing a diol, a diisocyanate and an acrylate having a hydroxyl group.
M-1: A reaction product of triethanolamine (1 mole), hexane-1,6-diisocyanate (3 moles), and 2-hydroxyethyl methacrylate (3 moles)
M-2: A reaction product of triethanolamine (1 mole), isophorone diisocyanate (3 moles), and 2-hydroxyethyl methacrylate (3 moles)
M-3: A reaction product of N-n-butyldiethanolamine (1 mole), 1,3-bis(1-cyanato-1-methylethyl)benzene (2 moles), and 2-hydroxypropylene-1-methacrylate-3-acrylate (2 moles)
M-4: A reaction product of N-n-butyldiethanolamine (1 mole), 1,3-di(cyanatomethyl)benzene (2 moles), and 2-hydroxypropylene-1-methacrylate-3-acrylate (2 moles)
M-5: A reaction product of N-methydiethanolamine (1 mole), tolylene-2,4-diisocyanate (2 moles), and 2-hydroxypropylene-1,3-dimethacrylate (2 moles)

In addition to the above, acrylates or methacrylates disclosed in Japanese Patent O.P.I. Publication Nos. 2-105238 and 1-127404 can be used.

In the invention, among these polymerizable monomers, a polymerizable monomer having in the molecule a hydroxyl group (hereinafter also referred to as hydroxyl group-containing polymerizable monomer) is especially preferred in solving the problems raised previously.

The hydroxyl group-containing polymerizable monomer is preferably a monomer represented by formula (PMOH) below.

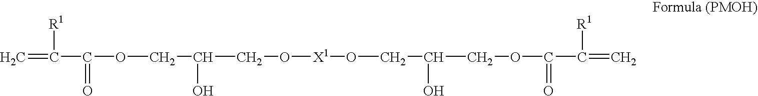

wherein R¹ represents a hydrogen atom or a methyl group; X¹ represents —CH₂CR²R³—CH₂—, —(CH₂—CH(OR⁴)—CH₂—O)m-CH₂—CH(OR⁵)CH₂—, —(CH(R⁶)CH₂O)n-CH(R⁶)CH₂—, —CO—X²—CO— or —X²—, in which R² and R³ independently represent a hydrogen atom, or a substituted or unsubstituted alkyl group, R⁴, R⁵ and R⁶ independently represent a hydrogen atom or an alkyl group, and X² represents an arylene group, an alkylene group or a cycloalkylene group; and m and n independently represent an integer of from 1 to 20.

Typical examples of the alkyl group of R² through R⁶ in formula (PMOH) include a methyl group, an ethyl group, a propyl group, an isopropyl group, a tert-butyl group, a pentyl group, a hexyl group and an octyl group. Among these alkyl groups, an alkyl group with a carbon atom number of from 1 to 10 is preferred, and an alkyl group with a carbon atom number of from 1 to 5 is more preferred. It is especially preferred that the alkyl group of R² and R³ is an alkyl group having a carbon atom number of from 1 to 4 and the alkyl group of R⁴ through R⁶ is a methyl group.

Examples of the substituent of the substituted alkyl group include an aryl group (for example, a phenyl group or a naphthyl group); an alkoxy group (for example, a methoxy group, an ethoxy group, a propoxy group, a pentyloxy group, or a hexyloxy group); an alkoxycarbonyl group (for example, a methyloxycarbonyl group, an ethyloxycarbonyl group, or a butyloxycarbonyl group); an acyl group (for example, an acetyl group, an ethylcarbonyl group, a propylcarbonyl group, a pentylcarbonyl group, or a cyclohexylcarbonyl group); an amido group (for example, a methylcarbonylamino group, an ethylcarbonylamino group, a dimethylcarbonylamino group, a propylcarbonylamino group, a pentylcarbonylamino group, a cyclohexylcarbonylamino group, or 2-ethylhexylcarbonylamino group); an amino group (for example, an amino group, an ethylamino group, a dimethylamino group, a butylamino group, a cyclopentylamino group, a 2-ethylhexylamino group, an anilino group, a naphthylamino group, or a 2-pyridylamino group); a halogen atom (for example, fluorine, chlorine, or bromine); and a hydroxyl group.

Among these substituents, an aryl group, an amino group, an amido group, an alkoxycarbonyl group or a hydroxyl group is preferred.

Examples of the alkylene group of X² include an ethylene group, a trimethylene group, a tetramethylene group, a propylene group, an ethylethylene group, a pentamethylene group, a hexamethylene group, and a 2,2,4-trimethylhexamethylene group.

Examples of the cycloalkylene group of X² include a cyclopentylene group and a cyclohexylene group.

Examples of the arylene group of X² include a phenylene group and a naphthylene group.

Examples of the compound represented by formula (PMOH) will be listed below, but the invention is not limited thereto.

| | R¹ | X¹ |
|---|---|---|
| PMOH-1 | —H | 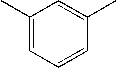 |
| PMOH-2 | —H | 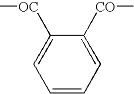 |
| PMOH-3 | —H | 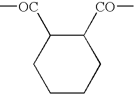 |
| PMOH-4 | —H | 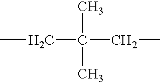 |
| PMOH-5 | —H | 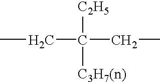 |
| PMOH-6 | —H | 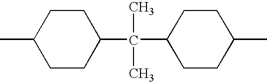 |
| PMOH-7 | —H | 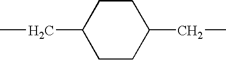 |
| PMOH-8 | —H | —(CH₂)₄— |
| PMOH-9 | —H | —(CH₂)₆— |
| PMOH-10 | —H | —CH₂CH₂— |
| PMOH-11 | —H | —CH₂CH₂OCH₂CH₂— |
| PMOH-12 | —H | —(CH₂CH₂O)₃CH₂CH₂— |
| PMOH-13 | —H | —(CH₂CH₂O)₈CH₂CH₂— |
| PMOH-14 | —H | —(CH₂CH₂O)₁₂CH₂CH₂— |
| PMOH-15 | —CH₃ | 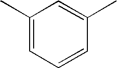 |
| PMOH-16 | —CH₃ | 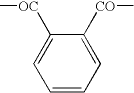 |
| PMOH-17 | —CH₃ | 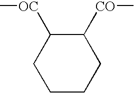 |
| PMOH-18 | —CH₃ | 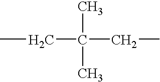 |
| PMOH-19 | —CH₃ | 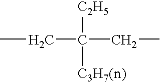 |
| PMOH-20 | —CH₃ | 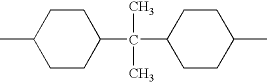 |
| PMOH-21 | —CH₃ | 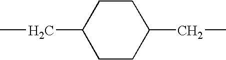 |
| PMOH-22 | —CH₃ | —(CH₂)₄— |
| PMOH-23 | —CH₃ | —(CH₂)₆— |
| PMOH-24 | —CH₃ | —CH₂CH₂— |
| PMOH-25 | —CH₃ | —CH₂CH₂OCH₂CH₂— |
| PMOH-26 | —CH₃ | —(CH₂CH₂O)₃CH₂CH₂— |
| PMOH-27 | —CH₃ | —(CH₂CH₂O)₈CH₂CH₂— |
| PMOH-28 | —CH₃ | —(CH₂CH₂O)₁₂CH₂CH₂— |

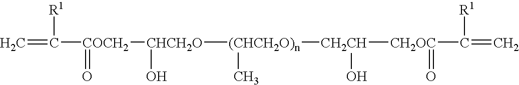

| | R¹ | n |
|---|---|---|
| PMOH-29 | —H | 2 |
| PMOH-30 | —H | ≈3 |
| PMOH-31 | —H | ≈11 |
| PMOH-32 | —CH₃ | 2 |
| PMOH-33 | —CH₃ | ≈3 |
| PMOH-34 | —CH₃ | ≈11 |

The polymerizable monomer content of the light sensitive layer is preferably from 30 to 70% by weight, and more preferably from 40 to 60% by weight.

### (Spectral Sensitizer)

The light sensitive layer in the invention contains a spectral sensitizer, and the spectral sensitizer is preferably one having absorption maximum in the wavelength regions of from 350 to 450 nm.

Examples of the spectral sensitizer include cyanine, merocyanine, porphyrin, a Spiro compound, ferrocene, fluorene, fulgide, imidazole, perylene, phenazine, phenothiazine, acridine, an azo compound, diphenylmethane, triphenylmethane, triphenylamine, cumarin derivatives, ketocumarin, quinacridone, indigo, styryl, pyrylium compounds, pyrromethene compounds, pyrazolotriazole compounds, benzothiazole compounds, barbituric acid derivatives, thiobarbituric acid derivatives, and ketoalcohol borate complexes.

As the spectral sensitizer, a coumarin derivative represented by formula (CS) above is preferred.

In formula (CS), R¹, R², R³, R⁴, R⁵ and R⁶ independently represent a hydrogen atom or a substituent. Examples of the substituent include an alkyl group (for example, a methyl group, an ethyl group, a propyl group, an isopropyl group, a t-butyl group, a pentyl group, a hexyl group, an octyl group, a dodecyl group, a tridecyl group, a tetradecyl group, or a pentadecyl group), a cycloalkyl group (for example, a cyclopentyl group or a cyclohexyl group), an alkenyl group (for example, a vinyl group or a allyl group), an alkinyl group (for example, a propargyl group), an aryl group (for example, a phenyl group, or a naphthyl group), a heteroaryl group (for example, a furyl group, a thienyl group, a pyridazinyl group, a pyrimidinyl group, a pyrazinyl group, a triazinyl group, an imidazolyl group, a pyrazolyl group, a thiazolyl group, a benzimidazolyl group, a benzoxazolyl group, a quinazolyl group, or a phthalazinyl group), a saturated heterocyclic group (for example, a pyrrolidinyl group, an imidazolidinyl group, a morpholinyl group or an oxazolidinyl group), an alkoxy group (for example, a methoxy group, an ethoxy group, a propoxy group, a pentyloxy group, a hexyloxy group, an octyloxy group, or a dodecyloxy group), a cycloalkoxy group (for example, a cyclopentyloxy group, or a cyclohexyloxy group), an aryloxy group (for example, a phenoxy group or a naphthyloxy group), an alkylthio group (for example, a methylthio group, an ethylthio group, a propylthio group, a pentylthio group, a hexylthio group, an octylthio group, or a dodecylthio group), a cycloalkylthio group (for example, a cyclopentylthio group or a cyclohexylthio group), an arylthio group (for example, a phenylthio group, or a naphthylthio group), an alkoxycarbonyl group (for example, a methyloxycarbonyl group, an ethyloxycarbonyl group, a butyloxycarbonyl group, an octyloxycarbonyl group, or a dodecyloxycarbonyl group), an aryloxycarbonyl group (for example, a phenyloxycarbonyl group, or a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, or a 2-pyridylaminosulfonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecycarbonyl group, a phenylcarbonyl group, a naphthylcarbonyl group, or a pyridylcarbonyl group), an acyloxy group (for example, an acetyloxy group, an ethylcarbonyloxy group, a butylcarbonyloxy group, an octylcarbonyloxy group, a dodecycarbonyloxy group, or a phenylcarbonyloxy group), an amido group (for example, a methylcarbonylamino group, an ethylcarbonylamino group, a dimethylcarbonylamino group, a propylcarbonylamino group, a pentylcarbonylamino group, a cyclohexylcarbonylamino group, 2-ethylhexylcarbonylamino group, an octylcarbonylamino group, a a dodecycarbonylamino group, a phenylcarbonylamino group, a naphthylcarbonylamino group, or a pyridylcarbonyl group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecyaminocarbonyl group, a phenylaminocarbonyl group, a naphthylaminocarbonyl group, or a 2-pyridylaminocarbonyl group), a ureido group (for example, a methylureido group, an ethylureido group, a pentylureido group, a cyclohexylureido group, an octylureido group, a dodecylureido group, a phenylureido group, a naphthylureido group, or a 2-pyridylureido group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, or a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, or a dodecylsulfonyl group), an arylsulfonyl group (for example, a phenylsulfonyl group, a naphthylsulfonyl group, or a 2-pyridylsulfoiiyl group), an amino group (for example, an amino group, an ethylamino group, a dimethylamino group, a butylamino group, a cyclopentylamino group, a 2-ethylhexylamino group, a dodecylamino group, an anilino group, a naphthylamino group, or a 2-pyridylamino group), a halogen atom (for example, fluorine, chlorine, or bromine), a cyano group, a nitro group, and a hydroxyl group. Any adjacent two of R¹, R², R³, R⁴, R⁵ and R⁶ may combine with each other to form a ring. R¹, R², R³, R⁴, R⁵ and R⁶ may have further an additional substituent and examples of the additional substituent include the same as those denoted above.

Coumarin derivatives are preferred in which in formula (CS), R⁵ is an amino group or a substituted amino group such as an alkylamino group, a dialkylamino group, an arylamino group, a diarylamino group, or an alkylarylamino group. The coumarin derivatives are preferably used in which the alkyl substituent of the substituted amino group in R⁵ combines with R⁴ or R⁶ to form a ring.

Coumarin derivatives are more preferred in which in addition to the above, at least one of R¹ and R² is an alkyl group (for example, a methyl group, an ethyl group, a propyl group, an isopropyl group, a t-butyl group, a pentyl group, a hexyl group, an octyl group, a dodecyl group, a tridecyl group, a tetradecyl group, or a pentadecyl group), a cycloalkyl group (for example, a cyclopentyl group or a cyclohexyl group), an alkenyl group (for example, a vinyl group or an allyl group), an aryl group (for example, a phenyl group, or a naphthyl group), a heteroaryl group (for example, a furyl group, a thienyl group, a pyridazinyl group, a pyrimidinyl group, a pyrazinyl group, a triazinyl group, an imidazolyl group, a pyrazolyl group, a thiazolyl group, a benzimidazolyl group, a benzoxazolyl group, a quinazolyl group, or a phthalazinyl group), a saturated heterocyclic group (for example, a pyrrolidinyl group, an imidazolidinyl group, a morpholinyl group or an oxazolidinyl group), an alkoxycarbonyl group (for example, a methyloxycarbonyl group, an ethyloxycarbonyl group, a butyloxycarbonyl group, an octyloxycarbonyl group, or a dodecyloxycarbonyl group), an aryloxycarbonyl group (for example, a phenyloxycarbonyl group, or a naphthyloxycarbonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecycarbonyl group, a phenylcarbonyl group, a naphthylcarbonyl group, or a pyridylcarbonyl group), an acyloxy group (for example, an acetyloxy group, an ethylcarbonyloxy group, a butylcarbonyloxy group, an octylcarbonyloxy group, a dodecycarbonyloxy group, or a phenylcarbonyloxy group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecyaminocarbonyl group, a phenylaminocarbonyl group, a naphthylaminocarbonyl group, or a 2-pyridylaminocarbonyl group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, or a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, or a dodecylsulfonyl group), an arylsulfonyl group (for example, a phenylsulfonyl group, a naphthylsulfonyl group, or a 2-pyridylsulfonyl group), a halogen atom (for example, fluorine, chlorine, or bromine), a cyano group, a nitro group or a halogenated alkyl group (for example, a trifluoromethyl group, a tribromomethyl group, or a trichloromethyl group).

Preferred examples of the coumarin derivatives will be listed below, but the invention is not limited thereto.

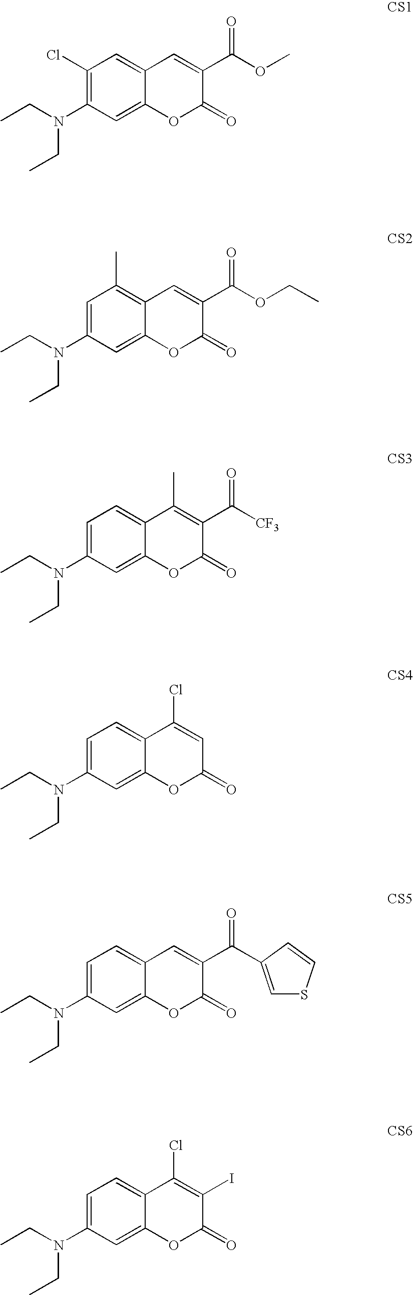

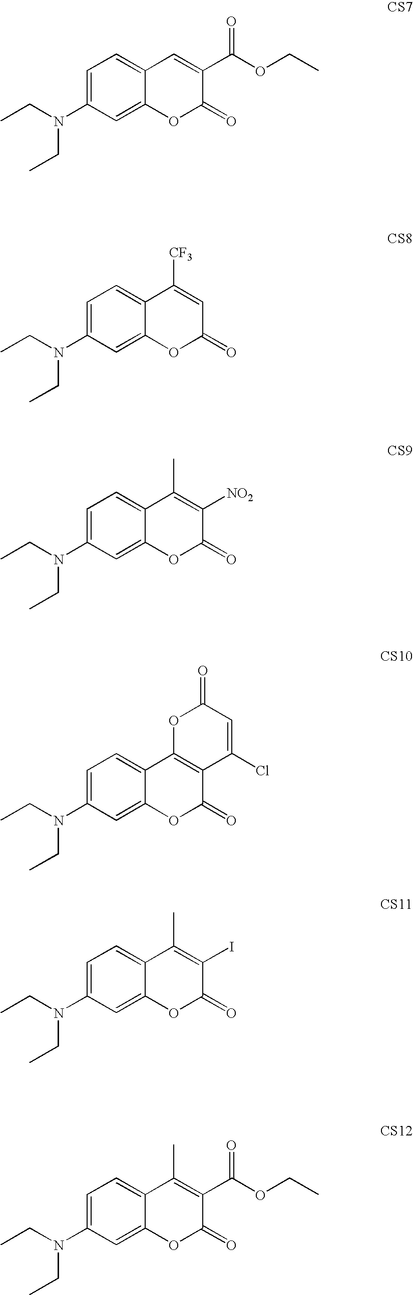

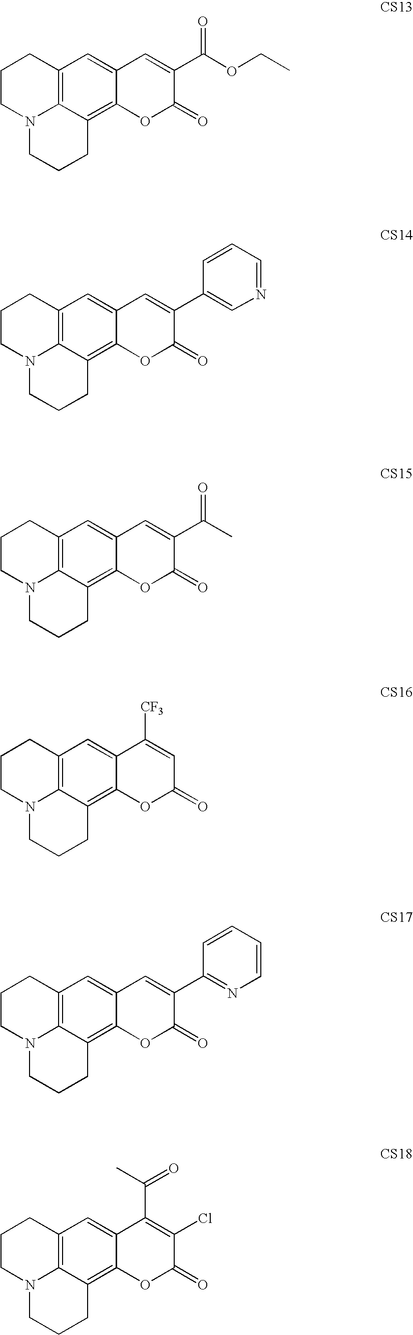

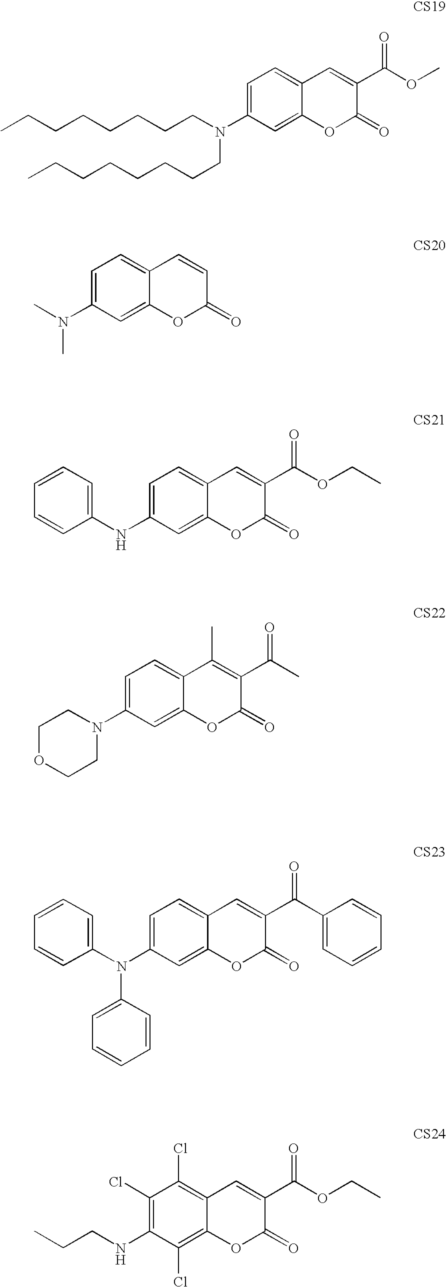

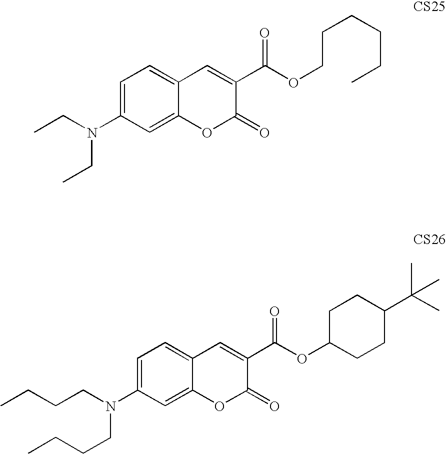

Besides the examples described above, there can be used coumarin derivatives B-1 through B-22 disclosed in Japanese Patent O.P.I. Publication No. 8-129258, coumarin derivatives D-1 through D-32 disclosed in Japanese Patent O.P.I. Publication No. 2003-12901, coumarin derivatives 1 through 21 disclosed in Japanese Patent O.P.I. Publication No. 2002-363206, coumarin derivatives 1 through 40 disclosed in Japanese Patent O.P.I. Publication No. 2002-363207, coumarin derivatives 1 through 34 disclosed in Japanese Patent O.P.I. Publication No. 2002-363208, or coumarin derivatives 1 through 56 disclosed in Japanese Patent O.P.I. Publication No. 2002-363209.

The spectral sensitizer content of the light sensitive layer is an amount providing a reflection density of the light sensitive layer in the range of from 0.1 to 1.2, the reflection density being measured employing light having a specific emission wavelength.

The spectral sensitizer content of the light sensitive layer meeting the range above is ordinarily from 0.1 to 10% by weight, although it greatly varies due to molecular extinction coefficient of the sensitizer or crystallinity of the sensitizer in the light sensitive layer.

### (Polymeric Binder)

The polymeric binder in the invention is a binder capable of carrying components contained in the light sensitive layer on a support. As the polymeric binder in the invention can be used a polyacrylate resin, a polyvinylbutyral resin, a polyurethane resin, a polyamide resin, a polyester resin, an epoxy resin, a phenol resin, a polycarbonate resin, a polyvinyl butyral resin, a polyvinyl formal resin, a shellac resin, or another natural resin. These resins can be used as an admixture of two or more thereof.

The polymeric binder in the invention is preferably a vinyl copolymer obtained by copolymerization of an acryl monomer, and more preferably a copolymer containing, as the copolymerization component, (a) a carboxyl group-containing monomer unit and (b) an alkyl methacrylate or alkyl acrylate unit.

Examples of the carboxyl group-containing monomer include an α,β-unsaturated carboxylic acid, for example, acrylic acid, methacrylic acid, maleic acid, maleic anhydride, itaconic acid, itaconic anhydride or a carboxylic acid such as a half ester of phthalic acid with 2-hydroxymethacrylic acid.

Examples of the alkyl methacrylate or alkyl acrylate include an unsubstituted alkyl ester such as methylmethacrylate, ethylmethacrylate, propylmethacrylate, butylmethacrylate, amylmethacrylate, hexylmethacrylate, heptylmethacrylate, octylmethacrylate, nonylmethacrylate, decylmethacrylate, undecylmethacrylate, dodecylmethacrylate, methylacrylate, ethylacrylate, propylacrylate, butylacrylate, amylacrylate, hexylacrylate, heptylacrylate, octylacrylate, nonylacrylate, decylacrylate, undecylacrylate, or dodecylacrylate; a cyclic alkyl ester such as cyclohexyl methacrylate or cyclohexyl acrylate; and a substituted alkyl ester such as benzyl methacrylate, 2-chloroethyl methacrylate, N,N-dimethylaminoethyl methacrylate, glycidyl methacrylate, benzyl acrylate, 2-chloroethyl acrylate, N,N-dimethylaminoethyl acrylate or glycidyl acrylate.

The polymeric binder in the invention can further contain, as another monomer unit, a monomer unit derived from the monomer described in the following items (1) through (14):

1) A monomer having an aromatic hydroxy group, for example, o-, (p- or m-) hydroxystyrene, or o-, (p- or m-) hydroxyphenylacrylate;

2) A monomer having an aliphatic hydroxy group, for example, 2-hydroxyethyl acrylate, 2-hydroxyethyl methacrylate, N-methylolacrylamide, N-methylolmethacrylamide, 4-hydroxybutyl acrylate, 4-hydroxybutyl methacrylate, 5-hydroxypentyl acrylate, 5-hydroxypentyl methacrylate, 6-hydroxyhexyl acrylate, 6-hydroxyhexyl methacrylate, N-(2-hydroxyethyl)acrylamide, N-(2-hydroxyethyl)methacrylamide, or hydroxyethyl vinyl ether;

3) A monomer having an aminosulfonyl group, for example, m- or p-aminosulfonylphenyl methacrylate, m- or p-aminosulfonylphenyl acrylate, N-(p-aminosulfonylphenyl) methacrylamide, or N-(p-aminosulfonylphenyl)acrylamide;

4) A monomer having a sulfonamido group, for example, N-(p-toluenesulfonyl)acrylamide, or N-(p-toluenesulfonyl)-methacrylamide;

5) An acrylamide or methacrylamide, for example, acrylamide, methacrylamide, N-ethylacrylamide, N-hexylacrylamide, N-cyclohexylacrylamide, N-phenylacrylamide, N-nitrophenylacrylamide, N-ethyl-N-phenylacrylamide, N-4-hydroxyphenylacrylamide, or N-4-hydroxyphenylmethacrylamide;

6) A monomer having a fluorinated alkyl group, for example, trifluoromethyl acrylate, trifluoromethyl methacrylate, tetrafluoropropyl methacrylate, hexafluoropropyl methacrylate, octafluoropentyl acrylate, octafluoropentyl methacrylate, heptadecafluorodecyl methacrylate, heptadecafluorodecyl methacrylate, or N-butyl-N-(2-acryloxyethyl)heptadecafluorooctylsulfonamide;

7) A vinyl ether, for example, ethyl vinyl ether, 2-chloroethyl vinyl ether, propyl vinyl ether, butyl vinyl ether, octyl vinyl ether, or phenyl vinyl ether;

8) A vinyl ester, for example, vinyl acetate, vinyl chroloacetate, vinyl butyrate, or vinyl benzoate;

9) A styrene, for example, styrene, methylstyrene, or chloromethystyrene;

10) A vinyl ketone, for example, methyl vinyl ketone, ethyl vinyl ketone, propyl vinyl ketone, or phenyl vinyl ketone;

11) An olefin, for example, ethylene, propylene, isobutylene, butadiene, or isoprene;

12) N-vinylpyrrolidone, N-vinylcarbazole, or N-vinylpyridine,

13) A monomer having a cyano group, for example, acrylonitrile, methacrylonitrile, 2-pentenenitrile, 2-methyl-3-butene nitrile, 2-cyanoethyl acrylate, or o-, m- or p-cyanostyrene;

14) A monomer having an amino group, for example, N,N-diethylaminoethyl methacrylate, N,N-dimethylaminoethyl acrylate, N,N-dimethylaminoethyl methacrylate, polybutadiene urethane acrylate, N,N-dimethylaminopropyl acrylamide, N,N-dimethylacrylamide, acryloylmorpholine, N-isoproplacrylamide, or N,N-diethylacrylamide.

Further another monomer may be copolymerized with the above monomer.

The polymeric binder in the invention is preferably a vinyl polymer having in the side chain a carboxyl group and a polymerizable double bond. As the polymer binder is also preferred an unsaturated bond-containing copolymer which is obtained by reacting a carboxyl group contained in the above vinyl copolymer molecule with for example, a compound having a (meth)acryloyl group and an epoxy group.

Examples of the compound having a (meth)acryloyl group and an epoxy group in the molecule include glycidyl acrylate, glycidyl methacrylate and an epoxy group-containing unsaturated compound disclosed in Japanese Patent O.P.I. Publication No. 11-271969. Further, an unsaturated bond-containing copolymer which is obtained by reacting a hydroxyl group contained in the above vinyl copolymer molecule with for example, a compound having a (meth)acryloyl group and an isocyanate group. Examples of the compound having a (meth)acryloyl group and an isocyanate group in the molecule include vinyl isocyanate, (meth)acryl isocyanate, 2-(meth)acroyloxyethyl isocyanate, m- or p-isopropenyl-α,α′-dimethylbenzyl isocyanate, and (meth)acryl isocyanate, or 2-(meth)acroyloxyethyl isocyanate is preferred.

The content of the vinyl polymer having in the side chain a carboxyl group and a polymerizable double bond is preferably from 50 to 100% by weight, and more preferably 100% by weight, based on the total weight of the polymer binder used.

It is preferred in solving the problems raised previously that the light sensitive layer contains a homopolymer or copolymer of N-vinyl pyrrolidone.

The comonomer contained in the N-vinyl pyrrolidone copolymer is not specifically limited, but the comonomer is preferably vinyl acetate.

The polymeric binder content of the light sensitive layer is preferably from 10 to 90% by weight, more preferably from 15 to 70% by weight, and still more preferably from 20 to 50% by weight, in view of sensitivity.

### (Various Additives)

The light sensitive layer in the invention is preferably added with a polymerization inhibitor, in order to prevent undesired polymerization of the ethylenically unsaturated compound during the manufacture or after storage of light sensitive planographic printing plate material.

Examples of the polymerization inhibitor include hydroquinone, p-methoxyphenol, di-t-butyl-p-cresol, pyrrogallol, t-butylcatechol, benzoquinone, 4,4′-thiobis(3-methyl-6-t-butylphenol), 2,2′-methylenebis(4-methyl-6-t-butylphenol), N-nitrosophenylhydroxylamine cerous salt, and 2-t-butyl-6-(3-t-butyl-6-hydroxy-5-mrthylbenzyl)-4-methylphenyl acrylate.

The polymerization inhibitor content is preferably 0.01 to 5% by weight based on the total solid content of the light sensitive layer. Further, in order to prevent undesired polymerization induced by oxygen, behenic acid or a higher fatty acid derivative such as behenic amide may be added to the layer. After the light sensitive layer is coated layer, the coated layer may be dried so that the higher fatty acid derivative is localized at the vicinity of the surface of the light sensitive layer. The content of the higher fatty acid derivative is preferably 0.5 to 10% by weight, based on the total solid content of the light sensitive layer.

A colorant can be also used. As the colorant can be used known materials including commercially available materials. Examples of the colorant include those described in revised edition “Ganryo Binran”, edited by Nippon Ganryo Gijutu Kyoukai (publishe by Seibunndou Sinkosha), or “Color Index Binran”. Pigment is preferred.

Kinds of the pigment include black pigment, yellow pigment, red pigment, brown pigment, violet pigment, blue pigment, green pigment, fluorescent pigment, and metal powder pigment. Examples of the pigment include inorganic pigment (such as titanium dioxide, carbon black, graphite, zinc oxide, Prussian blue, cadmium sulfide, iron oxide, or chromate of lead, zinc, barium or calcium); and organic pigment (such as azo pigment, thioindigo pigment, anthraquinone pigment, anthanthrone pigment, triphenedioxazine pigment, vat dye pigment, phthalocyanine pigment or its derivative, or quinacridone pigment).

Among these pigment, pigment is preferably used which does not substantially have absorption in the absorption wavelength regions of a spectral sensitizing dye used according to a laser for exposure. The absorption of the pigment used is not more than 0.05, obtained from the reflection spectrum of the pigment measured employing an integrating sphere and employing light with the wavelength of the laser used. The pigment content is preferably 0.1 to 107 % by weight, and more preferably 0.2 to 5% by weight, based on the total solid content of the photopolymerizable light sensitive layer composition.

A purple pigment or a blue pigment is preferably utilized in view of absorption of light with the aforesaid photosensitive wavelength region and image visibility after development. Such pigments include, for example, Cobalt Blue, cerulean blue, Alkali Blue, Phonatone Blue 6G, Victoria Blue Lake, metal-free Phthalocyanine Blue, Phthalocyanine Fast Sky Blue, Indathrene Blue, indigo, Dioxane Violet, Isoviolanthrone Violet, Indanthrone Blue and Indanthrone BC. Among them, more preferable are Phthalocyanine Blue and Dioxane Violet.

The light sensitive layer can contain surfactants as a coating improving agent as long as the performance of the invention is not jeopardized. Among these surfactants, a fluorine-contained surfactant is preferred.

Further, in order to improve physical properties of the cured light sensitive layer, the layer can contain an inorganic filler or a plasticizer such as dioctyl phthalate, dimethyl phthalate or tricresyl phosphate. The content of such a material is preferably not more than 10% by weight, based on the total solid content of the light sensitive layer.

The light sensitive planographic printing plate material of the invention is manufactured by preparing a light sensitive layer coating liquid containing the above-described components and then coating on a support the light sensitive layer coating liquid to form a light sensitive layer on the support.

The solvents used in the preparation of the light sensitive layer coating liquid include an alcohol such as sec-butanol, isobutanol, n-hexanol, or benzyl alcohol; a polyhydric alcohol such as diethylene glycol, triethylene glycol, tetraethylene glycol, or 1,5-pentanediol; an ether such as propylene glycol monobutyl ether, dipropylene glycol monomethyl ether, or tripropylene glycol monomethyl ether; a ketone or aldehyde such as diacetone alcohol, cyclohexanone, or methyl cyclohexanone; and an ester such as ethyl lactate, butyl lactate, diethyl oxalate, or methyl benzoate.

The coating amount of the light sensitive layer on a support is preferably from 0.1 to 10 g/m², and more preferably from 0.5 to 5 g/m².

### (Oxygen Shielding Layer)

An oxygen shielding layer or an oxygen shielding layer having anther protective function is optionally provided on the light sensitive layer.

It is preferred that the oxygen shielding layer is highly soluble in a developer as described later. The oxygen shielding contains preferably polyvinyl. Polyvinyl alcohol has the effect of preventing oxygen from transmitting. It is preferred that polyvinyl pyrrolidone is used in combination which has the effect of increasing adhesion between the oxygen shielding layer and the light sensitive layer.

Besides the above two polymers, the oxygen shielding layer may contain a water soluble polymer such as polysaccharide, polyethylene glycol, gelatin, glue, casein, hydroxyethyl cellulose, carboxymethyl cellulose, methyl cellulose, hydroxyethyl starch, gum arabic, sucrose octacetate, ammonium alginate, sodium alginate, polyvinyl amine, polyethylene oxide, polystyrene sulfonic acid, polyacrylic acid, or a water soluble polyamide.

In the planographic printing plate material in the invention, adhesive strength between the protective layer and the light sensitive layer is preferably not less than 35 mN/mm, more preferably not less than 50 mN/mm, and still more preferably not less than 75 mN/mm. Preferred composition of the protective layer is disclosed in Japanese Patent Application No. 8-161645.

The adhesive strength can be determined according to the following method. The adhesive tape with a sufficient adhesive force is applied on the protective layer, and then peeled together with the protective layer under the applied tape in the normal direction relative to the protective layer surface. Force necessary to peel the tape together with the protective layer is defined as adhesive strength.

The protective layer may further contain a surfactant or a matting agent. The protective layer is formed, coating on the photopolymerizable light sensitive layer a coating solution in which the above protective layer composition is dissolved in an appropriate coating solvent, and drying. The main solvent of the coating solution is preferably water or an alcohol solvent such as methanol, ethanol, or iso-propanol.

The coating amount of the protective layer is preferably 0.1 to 5.0 g/m², and more preferably 0.5 to 3.0 g/m².

In the invention, it is preferred in the invention that the oxygen shielding layer contains a surfactant represented by formula (SF1) or (SF2). Incorporation of the surfactant in the oxygen shielding layer minimizes contaminations at non-image portions during development. This effect is markedly exhibited when development is carried out with a solution with a low pH which is low in dissolution of light sensitive layer. Specifically, the effect is markedly exhibited when a light sensitive layer at unexposed portions is removed at 25° C., employing an aqueous solution with a pH of from 3.0 to 9.0 containing a water soluble resin and a surfactant.

The content of the surfactant in the oxygen shielding layer is not specifically limited, but it is preferably from 0.1 to 10% by weight and more preferably from 0.3 to 5% by weight, based on the total solid content of the oxygen shielding layer.

### (Support)

The support used in the invention is a plate or a sheet capable of carrying the light sensitive layer and preferably has a hydrophilic surface on the side on which the light sensitive layer is to be provided.

As the supports used in the invention, a plate of a metal such as aluminum, stainless steel, chromium or nickel, or a plastic film such as a polyester film, a polyethylene film or a polypropylene film, which is deposited or laminated with the above-described metal can be used. Further, a polyester film, a polyvinyl chloride film or a nylon film whose surface is subjected to hydrophilization treatment can be used. Among the above, the aluminum plate is preferably used, and may be a pure aluminum plate or an aluminum alloy plate.

As the aluminum alloy, there can be used various ones including an alloy of aluminum and a metal such as silicon, copper, manganese, magnesium, chromium, zinc, lead, bismuth, nickel, titanium, sodium or iron. In the aluminum plate for the support, the surface is roughened for water retention.

It is preferable that the aluminum plate is subjected to degreasing treatment for removing rolling oil prior to surface roughening (graining). The degreasing treatments include degreasing treatment employing solvents such as trichlene and thinner, and an emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting support is preferably subjected to desmut treatment in an aqueous solution of an acid such as phosphoric acid, nitric acid, sulfuric acid, chromic acid, or a mixture thereof, since smut is produced on the surface of the support. The surface roughening methods include a mechanical surface roughening method and an electrolytic surface roughening method electrolytically etching the support surface.

Though there is no restriction for the mechanical surface roughening method, a brushing roughening method and a honing roughening method are preferable.

Though there is no restriction for the electrolytic surface roughening method, a method, in which the support is electrolytically surface roughened in an acidic electrolytic solution, is preferred.

After the support has been electrolytically surface roughened, it is preferably dipped in an acid or an aqueous alkali solution in order to remove aluminum dust, etc. produced in the surface of the support. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used.

The dissolution amount of aluminum in the support surface is preferably 0.5 to 5 g/m². After the support has been dipped in the aqueous alkali solution, it is preferable for the support to be dipped in an acid such as phosphoric acid, nitric acid, sulfuric acid and chromic acid, or in a mixed acid thereof, for neutralization.

The mechanical surface roughening and electrolytic surface roughening may be carried out singly, and the mechanical surface roughening followed by the electrolytic surface roughening may be carried out.

After the surface roughening, anodizing treatment may be carried out. There is no restriction in particular for the method of anodizing treatment used in the invention, and known methods can be used. The anodizing treatment forms an anodization film on the surface of the support.

The support which has been subjected to anodizing treatment is optionally subjected to sealing treatment. For the sealing treatment, it is possible to use known methods using hot water, boiling water, steam, a sodium silicate solution, an aqueous dichromate solution, a nitrite solution and an ammonium acetate solution.

After the above treatment, the support is suitably undercoated with a water soluble resin such as polyvinyl phosphonic acid, a polymer or copolymer having a sulfonic acid in the side chain, or polyacrylic acid; a water soluble metal salt such as zinc borate; a yellow dye; an amine salt; and so on, for hydrophilization treatment. The sol-gel treatment support disclosed in Japanese Patent O.P.I. Publication No. 5-304358, which has a functional group capable of causing addition reaction by radicals as a covalent bond, is suitably used.

In the invention, the light sensitive layer coating liquid is coated on a support according to a conventional coating method, and dried to form a light sensitive layer on the support. Thus, a light sensitive planographic printing plate material of the invention is obtained.

Examples of the coating method include an air doctor coating method, a blade coating method, a wire bar coating method, a knife coating method, a dip coating method, a reverse roll coating method, a gravure coating method, a cast coating method, a curtain coating method, and an extrusion coating method.

A drying temperature of the coated light sensitive layer is preferably from 60 to 160° C., more preferably from 80 to 140° C., and still more preferably from 90 to 120° C.

The oxygen shielding layer is formed in the same manner as the light sensitive layer.

### (Imagewise Exposure)

As a light source for recording an image on the light sensitive planographic printing plate material of the invention, a laser with an emission wavelength of from 350 to 450 nm is preferably used.

Examples of light sources for imagewise exposure of the light sensitive planographic printing plate material include a He-Cd laser (441 nm), a combination of Cr: LiSAF and SHG crystals (430 nm) as a solid laser, and KnbO₃, ring resonator (430 nm), AlGaInN (350-450 nm) or AlGaInN semiconductor laser (InGaN type semiconductor laser available on the market, 400-410 nm) as a semiconductor type laser.

When a laser is used for exposure, which can be condensed in the beam form, scanning exposure according to an image can be carried out, and direct writing is possible without using any mask material. When the laser is employed for imagewise exposure, a highly dissolved image can be obtained, since it is easy to condense its exposure spot in minute size.

As a laser scanning method by means of a laser beam, there are a method of scanning on an outer surface of a cylinder, a method of scanning on an inner surface of a cylinder and a method of scanning on a plane. In the method of scanning on an outer surface of a cylinder, laser beam exposure is conducted while a drum around which a recording material is wound is rotated, in which main scanning is represented by the rotation of the drum, while sub-scanning is represented by the movement of the laser beam. In the method of scanning on an inner surface of a cylinder, a recording material is fixed on the inner surface of a drum, a laser beam is emitted from the inside, and main scanning is carried out in the circumferential direction by rotating a part of or an entire part of an optical system, while sub-scanning is carried out in the axial direction by moving straight a part of or an entire part of the optical system in parallel with a shaft of the drum. In the method of scanning on a plane, main scanning by means of a laser beam is carried out through a combination of a polygon mirror, a galvano mirror and an Fθ lens, and sub-scanning is carried out, moving a recording medium. The method of scanning on an outer surface of a cylinder and the method of scanning on an inner surface of a cylinder are suitable for high density image recording, since it is easier to increase accuracy of an optical system.

In the invention, imagewise exposure is carried out at a plate surface energy (an exposure energy at the surface of the planographic printing plate material) of from 10 to 500 mJ/cm², and more preferably from 10 to 300 mJ/cm². This exposure energy can be measured, employing a laser power meter PDGDO-3W produced by Ophir Optronics Inc.

### (Automatic Developing Machine)

It is advantageous that an automatic developing machine is used in order to remove unexposed portions of a light sensitive planographic printing plate material employing an aqueous solution with a pH at 25° C. of from 3.0 to 9.0 containing a water soluble resin and a surfactant. The automatic developing machine is preferably provided with a heating device for heating an exposed light sensitive planographic printing plate material upstream a device for removing unexposed portions thereof. Examples of the heating device include a heater employing radiation heat such as a ceramic heater, and a heater employing hot air obtained by heating air by a ceramic heater, and the like. A heater is preferred which can adjust the planographic printing plate material surface temperature to from 80 to 160° C. The automatic developing machine may be equipped with a pre-washing section for removing an oxygen shielding layer and a part of a light sensitive layer of a heated light sensitive planographic printing plate material. The pre-washing section is one with a nozzle for supplying washing water onto a heated light sensitive planographic printing plate material surface or a washing tank in which the plate is immersed. Further, the pre-washing section preferably has a roller-type brush for rubbing a light sensitive planographic printing plate material surface.

In a process for removing unexposed portions of a light sensitive planographic printing plate material employing an aqueous solution with a pH at 25° C. of from 3.0 to 9.0 containing a water soluble resin and a surfactant, a developing bath of an automatic developing machine can be used which is used for development of a conventional light sensitive planographic printing plate material. It is preferred that the developing bath has a member for adjusting temperature of the aqueous solution to a specific temperature, preferably from 20 to 35° C. It is preferred that the automatic developing machine is equipped with a means for automatically introducing the aqueous solution in a necessary amount into the developing bath, and a means for discharging an excess of the aqueous solution. It is preferred that the automatic developing machine comprises a means for detecting a planographic printing plate material to be transported, a means for calculating the area to be processed of the planographic printing plate material based on the detection, or a means for controlling a replenishing amount of a replenisher to be replenished or replenish timing based on the detection and calculation. It is also preferred that the automatic developing machine comprises a means for controlling a temperature of the aqueous solution, a means for detecting a pH and/or electric conductivity of the aqueous solution, or a means for controlling a replenishing amount of a replenisher to be replenished, a replenishing amount of water to be replenished and/or the replenishing timing based on the detected pH and/or electric conductivity.

### EXAMPLES

Next, the present invention will be explained employing the following examples, but is not limited thereto. In the examples, “parts” is parts by weight, unless otherwise specified.

### Examples 1 Through 13 and Comparative Examples 1 Through 3

### (Preparation of Support)

A 0.30 mm thick and 1030 mm wide aluminum plate (material JIS A 1050) was successively treated according to the following procedures:

(a) The aluminum plate was subjected to etching treatment, in which the aluminum plate was sprayed with a 70° C. solution having a caustic soda concentration of 2.6 weight % and an aluminum ion concentration of 6.5 weight % to dissolve the aluminum by 0.3 g/m², and was washed by means of a water spray.

(b) Desmut treatment was performed by spraying the aluminum plate with an aqueous 1% by weight nitric acid solution (containing aluminum ion of 0.5 weight %) at 30° C., followed by washing by a water spray.

(c) The resulting aluminum plate was subjected to continuous electrolytic roughening treatment, utilizing an alternating voltage of 60 Hz, in a 21° C. electrolytic solution containing 1.1% by weight hydrochloric acid, 0.5% by weight of an aluminum ion and 0.5% by weight of acetic acid, and was washed by water spray. The electrolytic roughening treatment was performed employing a sine wave alternating current at a TP (time taken for current to reach from zero to the peak value) of 2 msec, and employing a carbon electrode as a counter electrode, wherein the current density was 50 A/dm² in terms of effective value, and the quantity of electricity supplied was 900 C/dm².

(d) The resulting aluminum plate was desmutted for 10 seconds in an aqueous 20% by weight phosphoric acid solution having an aluminum ion concentration of 0.5% by weight at 60° C., and washed with water spray.

(e) Employing a conventional anodizing treatment apparatus employing a two-step power-supplied electrolysis method (in which a length of each of the first and second electrolysis section is 6 m, the first power supply section is 3 m long, the second power supply section is 3 m long, and a length of each of the first and second power supply electrodes is 2.4 m), anodizing treatment was performed at 38° C. in a solution having a sulfuric acid concentration of 170 g/l (having an aluminum ion concentration of 0.5 weight %) in the electrolysis section. Thereafter, the plate was sprayed with water and washed.

At this time, in the anodizing treatment apparatus, electric current from power source flowed to the first power supply electrode arranged in the first power supply section, then to the aluminum plate through the electrolytic solution to form an oxidized film on the surface of the aluminum plate in the first electrolysis section, and passed through the electrolysis electrode arranged in the first power supply section to return to the power source.

On the other hand, electric current from a power source flowed to the second power supply electrode arranged in the second power supply section, then similarly to the aluminum plate through the electrolytic solution to form an oxidized film on the surface of the aluminum plate in the second electrolysis section. The quantity of electricity supplied from a power source to the first power supply section and the quantity of electricity supplied from a power source to the second power supply section were same, and the power supply electric current density on the oxidized film surface at the second power supply section was approximately 25 A/dm². In the second power supply section, power was supplied from the surface of the oxidized film of 1.35 g/m². The final amount of the oxidized film was 2.7 g/m². The resulting aluminum plate was washed with water, then subjected to hydrophilization treatment in which the plate was immersed in a 85° C. aqueous 0.4% by weight polyvinyl phosphonic acid solution for 30 seconds, washed with water, and dried with an infrared heater. Thus, an aluminum support was obtained. The aluminum support obtained above had a centerline average surface roughness (Ra) of 0.65 μm.

### (Preparation of Light Sensitive Planographic Printing Plate Material Samples)

The following photopolymerizable light sensitive layer coating solution was coated on the resulting support through a wire bar, and dried at 95° C. for 1.5 minutes to give a light sensitive layer having a dry thickness of 1.5 g/m². After that, the following oxygen shielding layer coating solution was coated on the photopolymerizable light sensitive layer using a wire bar, and dried at 65° C. for 3 minutes to give an oxygen shielding layer with a dry thickness of 2.0 g/m². Thus, inventive light sensitive planographic printing plate material samples 1 through 13 and comparative light sensitive planographic printing plate material samples 1 through 3 were prepared.

### (Photopolymerizable Light Sensitive Layer Coating Solution)

| | |
|---|---|
| Polymerizable monomer 1 | 5.0 parts |
| Polymerizable monomer 2 | 25.0 parts |
| Polymerizable monomer 3 | 25.0 parts |
| Spectral Sensitizer (as shown in Table 1) | 3.5 parts |
| N-Carboxymethylacridone | 3.5 parts |
| Tribromoacetyl compound BR-20 | 0.3 parts |
| N-vinyl pyrrolidone-vinyl acetate copolymer | 20.0 parts |
| VA64 (produced by BASF Co., Ltd.) | |
| Poly(N-vinyl pyrrolidone) | 20.0 parts |
| Luvitec K30 (produced by BASF Co., Ltd.) | |
| Acetylene type surfactant | 0.5 parts |
| Surfinol 465, produced by Air Products Co., Ltd.) | |
| Surfactant (as shown in Table 1) | 1.0 part |
| Phthalocyanine pigment dispersion | 3.0 parts |
| (MHI 454, produced by Mikuni Shikiso Co., Ltd.) | |
| Polymerization initiator (as shown in Table 1) | 3.0 part |
| Water | 450 parts |
| Ethanol | 450 parts |

Polymerizable monomer 1

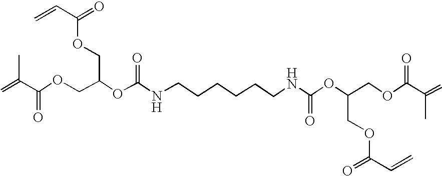

Polymerizable monomer 2

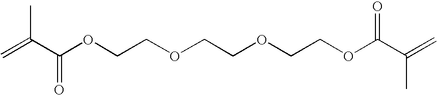

Polymerizable monomer 3

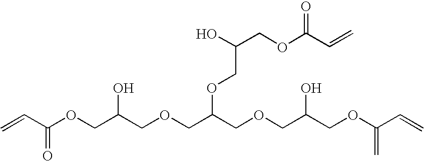

### (Oxygen Shielding Layer Coating Solution)

| | |
|---|---|
| Polyvinyl alcohol (GL-05, produced | 90 parts |
| by Nippon Gosei Kagaku Co., Ltd.) | |
| Poly(N-vinyl pyrrolidone) (Luvitec K-30, | 5 parts |
| produced by ISP Japan Co., Ltd.) | |
| Polyethylene imine | 5 parts |
| (Lupasol WF, available from BASF Co., Ltd.) | |
| Surfactant (as shown in Table 1) | 0.5 parts |
| Water | 900 parts |

### (Evaluation)

Employing a plate setter News (produced by ECRM Co., Ltd.) installed with a light source emitting a 405 nm light, the light sensitive planographic printing plate material samples obtained above were imagewise exposed under yellow safelight at a resolving degree of 1200 dpi and at a screen line number of 100 lpi, while varying exposure energy.

Under red safelight, each of the exposed samples was heated at 105° C. for 30 seconds, and then washed with a spraying tap water for 15 seconds to remove the oxygen shielding layer, wherein a part of light sensitive layer at unexposed portions. The resulting sample was immersed (subjected to development treatment) for 20 seconds in the following aqueous solution 1 while rubbing the light sensitive layer surface with a sponge to completely remove the light sensitive layer at the unexposed portions, and dried. Thus, a planographic printing plate sample was prepared.

### (Aqueous Solution 1)

| | |
|---|---|
| White dextrin | 5.0 wt. % |
| Starch hydroxypropyl ether | 10.0 wt. % |
| Gum arabic | 1.0 wt. % |
| Ammonium phosphate | 0.1 wt. % |
| Sodium dilaurylsuccinate | 0.15 wt. % |
| Polyoxyethylene naphthyl ether | 0.5 wt. % |
| Polyoxyethylene-polyoxypropylene block | 0.3 wt. % |
| copolymer (with an ethylene oxide content | |
| of 50 mol % and a molecular weight of 5000) | |
| Ethylene glycol | 1.0 wt. % |
| 1,2-Benzoisothiazoline-3-one | 0.005 wt. % |
| Water | 82.4 wt. % |
| Phosphoric acid | Amount providing a pH |
| | of 3.0 at 25° C. |

Employing the resulting printing plate, printing was carried out on a press (DAIYA1F-1 produced by Mitsubishi Jukogyo Co., Ltd.), wherein a coat paper, printing ink (Toyo King Highecho Magenta M″ produced by Toyo Ink Manufacturing Co., Ltd.), and dampening water (SG-51, H solution produced by Tokyo Ink Co., Ltd., Concentration: 1.5%) were used.

### (Sensitivity)

Printing was carried out to obtain 50 prints. Image portions of the 50^{th} print were observed. The minimum exposure energy at which the normal ink density was obtained in the image portions of the 50^{th} print was defined ad sensitivity. The less the minimum exposure energy is, the higher the sensitivity.

### (Contamination Resistance)

Non-image portions in the prints were observed according to the following evaluation criteria:
A: No contamination was observed in the non-image portions.
B: Contamination was hardly observed in the non-image portions.
C: Partial spot-shaped contamination was observed in the non-image portions.
D: Uniform but light contamination was observed in the non-image portions.
E: Uniform and apparent contamination was observed in the non-image portions.

### (Storage Stability or Sensitivity Variation After Storage)

The planographic printing plate material sample obtained above was stored at 55° C. for three days in a thermostat. Sensitivity of the resulting sample was determined in the same manner as above, and the sensitivity ratio of sensitivity after storage to sensitivity before storage was determined and evaluated as a measure of storage stability.

The closer to 100% ratio is, the higher the storage stability.

The results are shown in Table 1.

TABLE 1

| | Surfactant | Surfactant | | |
|---|---|---|---|---|
| | in Light | in Oxygen | | |
| Sample | Sensitive | Shielding | Polymerization | Spectral |
| No. | Layer | Layer | Initiator | Sensitizer |
| 1 (Inv.) | SF1-2 | Surfinol 465 | 1-1 | CS25 |
| 2 (Inv.) | SF1-3 | Surfinol 465 | 1-1 | CS25 |
| 3 (Inv.) | SF1-5 | Surfinol 465 | 1-1 | CS25 |
| 4 (Inv.) | SF2-2 | Surfinol 465 | 1-1 | CS25 |
| 5 (Inv.) | SF2-5 | Surfinol 465 | 1-1 | CS25 |
| 6 (Inv.) | SF1-2 | Surfinol 465 | 1-2 | CS25 |
| 7 (Inv.) | SF1-2 | Surfinol 465 | 1-1 | DR-1 |
| 8 (Inv.) | SF1-2 | Surfinol 465 | 1-2 | DR-1 |
| 9 (Inv.) | F-178K & | SF1-2 | 1-2 | CS25 |
| | BYK337 | | | |
| 10 (Inv.) | F-178K & | SF1-5 | 1-2 | CS25 |
| | BYK337 | | | |
| 11 (Inv.) | F-178K & | SF2-2 | 1-2 | CS25 |
| | BYK337 | | | |
| 12 (Inv.) | SF1-2 | SF2-2 | 1-2 | CS25 |
| 13 (Inv.) | SF1-5 | SF1-5 | 1-2 | CS25 |
| 1 (Comp.) | F-178K & | Surfinol 465 | 1-1 | CS25 |
| | BYK337 | | | |
| 2 (Comp.) | F-178K & | Surfinol 465 | 1-1 | DR-1 |
| | BYK337 | | | |
| 3 (Comp.) | F-178K & | Surfinol 465 | 1-2 | DR-1 |
| | BYK337 | | | |

| | | | Storage |
|---|---|---|---|
| | Sensitivity | Contamination | Stability |
| Sample No. | (μJ/cm²) | Resistance | (%) |
| 1 (Inv.) | 80 | 5 | 95 |
| 2 (Inv.) | 80 | 5 | 95 |
| 3 (Inv.) | 70 | 5 | 97 |
| 4 (Inv.) | 60 | 5 | 96 |
| 5 (Inv.) | 60 | 4 | 94 |
| 6 (Inv.) | 60 | 5 | 95 |
| 7 (Inv.) | 95 | 4 | 93 |
| 8 (Inv.) | 100 | 4 | 92 |
| 9 (Inv.) | 70 | 4 | 91 |
| 10 (Inv.) | 70 | 4 | 90 |
| 11 (Inv.) | 70 | 4 | 92 |
| 12 (Inv.) | 70 | 5 | 97 |
| 13 (Inv.) | 70 | 5 | 96 |
| 1 (Comp.) | 120 | 3 | 70 |
| 2 (Comp.) | 125 | 3 | 65 |
| 3 (Comp.) | 130 | 2 | 65 |

Inv.: Inventive,
Comp.: Comparative
F-178K: Fluorine-containing surfactant produced by Dainippon Ink Co., Ltd.
BYK337: Silicon-containing surfactant produced by BYK Chemie Co., Ltd. (The amount by weight of BYK337 was 1.5 times of that of F-178K.)
Surfinol 465: Surfactant available from Air Products Co. Ltd.
DR-1: 1,4-Bis(4-methoxystyryl)benzene
1-1: η6-Cumene-(η5-cyclopentadienyl)iron hexafluorophosphate
1-2: 2,2′-Bis(2-chlorophenyl)4,5,4′,5′-tetraphenyl-biimidazole

### Example 14 and Comparative Example 4

Inventive light sensitive planographic printing plate material sample 14 was prepared in the same manner as inventive sample 6 above, except that PMOH-26 was used instead of Polymerizable monomer 3. Comparative light sensitive planographic printing plate material sample 4 was prepared in the same manner as comparative sample 1 above, except that PMOH-26 was used instead of Polymerizable monomer 3. The resulting samples were evaluated for sensitivity, contamination resistance and storage stability in the same manner as above. The results are shown in Table 2.

TABLE 2

| | | | Storage |
|---|---|---|---|
| | Sensitivity | Contamination | Stability |
| Sample No. | (μJ/cm²) | Resistance | (%) |
| 14 (Inventive) | 60 | 5 | 95 |
| 4 (Comparative) | 120 | 3 | 90 |

### Example 15 and Comparative Example 5

Inventive light sensitive planographic printing plate material sample 14 and Comparative light sensitive planographic printing plate material sample 4 were processed in the same manner as above, except that the exposed and heated samples were immersed for 15 seconds in the aqueous solution 1 without being washed with a spraying tap water for 15 seconds to remove the oxygen shielding layer. The resulting samples were evaluated for sensitivity, contamination resistance and storage stability in the same manner as above. The results are shown in Table 3.

In the above when an aqueous solution in which the pH of the aqueous solution (1) was changed to 9 was employed, the same results as above were obtained.

TABLE 3

| | | | Storage |
|---|---|---|---|
| | Sensitivity | Contamination | Stability |
| Sample No. | (μJ/cm²) | Resistance | (%) |
| 15 (Inventive) | 75 | 5 | 95 |
| 5 (Comparative) | 120 | 3 | 90 |

### Example 16 and Comparative Example 6

Inventive light sensitive planographic printing plate material sample 14 and Comparative light sensitive planographic printing plate material sample 4 were processed in the same manner as above, except that the exposed samples were not heated at 105° C. for 30 seconds. The resulting samples were evaluated for sensitivity, contamination resistance and storage stability in the same manner as above. The results are shown in Table 4.

TABLE 4

| | | | Storage |
|---|---|---|---|
| | Sensitivity | Contamination | Stability |
| Sample No. | (μJ/cm²) | Resistance | (%) |
| 16 (Inventive) | 90 | 5 | 92 |
| 6 (Comparative) | 150 | 3 | 85 |

As is apparent from Tables 1 through 4, inventive samples provide high sensitivity and high storage stability as compared with comparative samples, and inventive samples exhibiting high contamination resistance even when it is subjected to development treatment employing a solution with a low pH.

Further, comparative samples 1 through 3 were processed in the same manner as above, except that an aqueous solution in which Compound SF1-2 or Compound SF2-2 was further added to aqueous solution (1) was used instead of aqueous solution (1), and evaluated for contamination resistance in the same manner as above. It proved that contamination reduced to half by the use of the aqueous solution containing Compound SF1-2 or Compound SF2-2.

What is claimed is:

1. A light sensitive planographic printing plate material comprising a support and provided thereon, a light sensitive layer containing a spectral sensitizer, a polymerization initiator, a polymerizable monomer and a polymeric binder, wherein the light sensitive planographic printing plate material comprises a surfactant represented by the following formula (SF1) or (SF2),
R₁—O—(R₂—O)ₙ—H Formula (SF1)
wherein R₁ represents a substituted or unsubstituted branched alkyl group having a total carbon atom number of not more than 20 or a substituted or unsubstituted branched alkyl amino group having a total carbon atom number of not more than 20; R₂ represents a substituted or unsubstituted alkylene group having a carbon atom number of from 1 to 10; n represents an integer of 2 to 100, provided that plural R₂s may be the same or different,
R₃O—[CH₂CH(CH₃)O]ₗ(CH₂CH₂O)ₘ—H Formula (SF2)
wherein R₃ represents an alkyl group having a carbon atom number of from 4 to 10; l represents an integer of from 1 to 3; and m represents an integer of from 1 to 100.

2. The light sensitive planographic printing plate material of claim 1, wherein the light sensitive layer contains the surfactant represented by formula (SF1) or (SF2).

3. The light sensitive planographic printing plate material of claim 1, wherein an oxygen shielding layer containing polyvinyl alcohol is provided on the light sensitive layer.

4. The light sensitive planographic printing plate material of claim 3, wherein the oxygen shielding layer contains the surfactant represented by formula (SF1) or (SF2).

5. The light sensitive planographic printing plate material of claim 1, wherein the polymerization initiator is an iron-arene complex.

6. The light sensitive planographic printing plate material of claim 1, wherein the polymerization initiator is a hexaarylbiimidazole.

7. The light sensitive planographic printing plate material of claim 1, wherein the spectral sensitizer is a coumarin derivative represented by formula (CS), 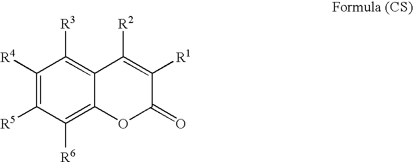
wherein R¹ through R⁶ independently represent a hydrogen atom or a substituent.

8. The light sensitive planographic printing plate material of claim 1, wherein the polymerizable monomer is a polymerizable compound having in the molecule a hydroxyl group.

9. The light sensitive planographic printing plate material of claim 1, wherein the light sensitive layer contains, as the polymeric binder, a homopolymer or copolymer of N-vinyl pyrrolidone.

10. A manufacturing process of a planographic printing plate comprising the steps of:
(a) imagewise exposing the light sensitive planographic printing plate material of claim 1, employing a laser; and
(b) removing the light sensitive layer at unexposed portions at 25° C. with an aqueous solution with a pH of 3.0 to 9.0 containing a water soluble resin and a surfactant.

11. The manufacturing process of claim 10, wherein the laser has an emission wavelength of from 350 to 450 nm.

12. The process of claim 10, wherein the surfactant contained in the aqueous solution is a surfactant represented by formula (SF1) or (SF2).

13. The manufacturing process of claim 10, between the steps (a) and (b), further comprising the step of heating the exposed light sensitive planographic printing plate material so that the surface temperature of the exposed material is from 80 to 160° C.

14. A manufacturing process of a planographic printing plate comprising the steps of:
(a) imagewise exposing the light sensitive planographic printing plate material of claim 3, employing a laser;
(b) removing the oxygen shielding layer and a part of the light sensitive layer of the exposed material, employing water; and
(c) then removing the light sensitive layer at unexposed portions with an aqueous solution with a pH at 25° C of 3.0 to 9.0 containing a water soluble resin and a surfactant.

15. The manufacturing process of claim 14, wherein the laser has an emission wavelength of from 350 to 450 nm.

16. The process of claim 14, wherein the surfactant contained in the aqueous solution is a surfactant represented by formula (SF1) or (SF2).

17. The manufacturing process of claim 14, between the steps (a) and (b), further comprising the step of heating the exposed light sensitive planographic printing plate material so that the surface temperature of the exposed material is from 80 to 160° C.
